(19) United States
(12) Patent Application Publication
(10) Pub. No.: US 2026/0060030 A1
(43) Pub. Date: Feb. 26, 2026

(54) SEMICONDUCTOR PROCESSING PLATFORM FOR REDUCED ENERGY CONSUMPTION

(71) Applicant: TOKYO ELECTRON LIMITED, Tokyo (JP)

(72) Inventors: Ronald NASMAN, Albany, NY (US); Peter DELIA, Albany, NY (US)

(73) Assignee: TOKYO ELECTRON LIMITED, Tokyo (JP)

(21) Appl. No.: 19/307,858

(22) Filed: Aug. 22, 2025

Related U.S. Application Data
(60) Provisional application No. 63/686,350, filed on Aug. 23, 2024.

(51) Int. Cl. H01L 21/67

(52) U.S. Cl. CPC H01L 21/67098; H01L 21/67028; H01L 21/67248

(57) ABSTRACT

A system includes one or more semiconductor processing chambers, and a processing fluid supply system including an input portion configured to receive a first fluid from a first fluid source, a heater fluidly coupled to the input portion and configured to heat the first fluid, and a heated flow portion fluidly coupled to the heater and configured to deliver a heated processing fluid including the first fluid heated by the heater to the one or more semiconductor processing chambers. A waste system is configured to receive hot waste fluid from the heated flow portion and/or a semiconductor processing chamber. A heat exchanger includes a supply-side flow path in fluid communication with the input portion and a heat delivery-side flow path in fluid communication with the waste system. The heat exchanger is configured to transfer thermal energy from the waste system to the input portion to heat the first fluid.

### INCORPORATION BY REFERENCE

This present disclosure claims the benefit of U.S. Provisional Application No. 63/686,350, filed on Aug. 23, 2024, the entire content of which is incorporated herein by reference in its entirety. The present disclosure also relates to the patent application having Attorney Docket Number 558586US and titled SEMICONDUCTOR PROCESSING PLATFORM USING CASCADED HEAT PUMPS FOR REDUCED ENERGY CONSUMPTION; the patent application having Attorney Docket Number 558585US and titled SEMICONDUCTOR PROCESSING PLATFORM USING PLURAL HEAT PUMPS FOR REDUCED ENERGY CONSUMPTION; and the patent application having Attorney Docket Number 558734US and titled SEMICONDUCTOR PROCESSING PLATFORM USING HEAT PUMP FOR REDUCED ENERGY CONSUMPTION. These applications are filed on even date with the present application and each application is incorporated herein by reference in its entirety.

### FIELD OF THE INVENTION

This disclosure relates to integrated circuits and a semiconductor processing platform for semiconductor fabrication, specifically for wafer cleaning process.

### BACKGROUND

In semiconductor and integrated circuit manufacturing, tool platforms are equipped with one or more processing chamber modules to perform various functions on the workpiece from which electronic devices are fabricated. Such processing can include etching materials, depositing materials, cleaning material surfaces or material interfaces, annealing materials, implantation materials, doping materials, or the like. These processing chamber modules can include a liquid-phase, a gas-phase, a solid-phase, or a mix of phases during the processing. Oftentimes, thermal systems are employed to control the processing temperature in the processing chamber modules either at an elevated temperature or a depressed temperature relative to room or atmospheric temperature. The heating and cooling systems are deployed to control the temperature which typically exhausts thermal energy without recapturing it. There is a need to improve the tools, the tool platforms, or the manufacturing facilities to achieve higher energy efficiency.

### SUMMARY

The present disclosure relates to a semiconductor device and methods of forming the semiconductor device.

An aspect (1) disclosed herein is a system including: one or more semiconductor processing chambers; a processing fluid supply system including: an input portion configured to receive a first fluid from a first fluid source, a heater fluidly coupled to the input portion and configured to heat the first fluid, and a heated flow portion fluidly coupled to the heater and configured to deliver a heated processing fluid including the first fluid heated by the heater to the one or more semiconductor processing chambers. A waste system is configured to receive hot waste fluid from at least one of the heated flow portion and the one or more semiconductor processing chambers; and a heat exchanger including a supply-side flow path in fluid communication with the input portion and a heat delivery-side flow path in fluid communication with the waste system, wherein the heat exchanger is configured to transfer thermal energy from the waste system to the input portion to heat the first fluid prior to heating by the heater.

Another aspect (2) includes the system of aspect (1), wherein the heated flow portion includes a recirculation tank configured to input the first fluid heated by the heater and to output the heated processing fluid for delivery to the one or more semiconductor processing chambers.

Another aspect (3) includes the system of aspect (2), wherein the heated flow portion includes a recirculation loop configured to return the heated processing fluid output from the recirculation tank back into the recirculation tank.

Another aspect (4) includes the system of aspect (3), wherein the recirculation loop includes a circulation pump and a recirculation heater.

Another aspect (5) includes the system of aspect (2), wherein the recirculation tank is configured to input at least a second fluid for mixing with the first fluid to provide the heated processing fluid for delivery to the one or more semiconductor processing chambers.

Another aspect (6) includes the system of aspect (1), further including a rinse delivery system configured to provide a rinse fluid to the one or more semiconductor processing chambers.

Another aspect (7) includes the system of aspect (6), wherein the rinse delivery system is configured to receive the first fluid from the first fluid source and provide the first fluid as the rinse fluid to the one or more semiconductor processing chambers.

Another aspect (8) includes the system of aspect (6), further including at least one valve configured to flow either the heated processing fluid or the rinse fluid to the semiconductor processing chamber.

Another aspect (9) includes the system of aspect (1), wherein the one or more semiconductor processing chambers includes a batch wafer cleaning chamber or a single wafer cleaning chamber.

Another aspect (10) includes the system of aspect (1), wherein the one or more semiconductor processing chambers includes a plurality semiconductor processing chambers.

Another aspect (11) includes the system of aspect (2), wherein the waste system includes an exchange tank configured to store hot waste fluid from the recirculation tank and selectively flow stored hot waste fluid to the heat delivery-side flow path of the heat exchanger.

Another aspect (12) includes the system of aspect (11), wherein the waste system includes a drain line configured to drain the hot waste fluid from the recirculation tank into the exchange tank.

Another aspect (13) includes the system of aspect (12), wherein the drain line includes at least one flow valve configured to selectively flow the hot waste fluid from the recirculation tank into the exchange tank, and selectively flow the stored hot waste fluid to the heat delivery-side flow path of the heat exchanger.

Another aspect (14) includes the system of aspect (1), wherein the input portion of the processing fluid supply system includes a pre-heating flow system configured to pre-heat the first fluid.

Another aspect (15) includes the system of aspect (14), wherein the pre-heating flow system includes a pre-heating tank configured to store pre-heated first fluid and flow stored pre-heated first fluid to the heater.

Another aspect (16) includes the system of aspect (15), wherein the pre-heating flow system further includes a pre-heat pump and at least one flow valve configured to selectively flow the stored pre-heated first fluid to the heater.

Another aspect (17) includes the system of aspect (15), wherein the pre-heating tank further includes a heater configured to heat fluid within the pre-heating tank.

Another aspect (18) is a method including: providing a fluid supply system coupled to at least one semiconductor processing chamber configured to process a semiconductor substrate; flowing a first fluid via an input portion of the fluid supply system to a heater; and using the heater to heat the first fluid and outputting a heated first fluid to a heated flow portion of the fluid supply system which flows a heated processing fluid including the heated first fluid to the semiconductor processing chamber. Also included is collecting hot waste fluid from at least one of the heated flow portion of the fluid supply system and the semiconductor processing chamber; and coupling thermal energy from the hot waste fluid to the first fluid prior to using the heater to heat the first fluid such that a thermal load on the heater is reduced.

Another aspect (19) includes the method of aspect (18), further including: providing a recirculation tank on the input portion of the fluid supply system; draining the hot waste fluid from the recirculation tank to an exchange tank configured to store the drained hot waste fluid; selectively flowing stored hot waste fluid from the exchange tank to a thermal coupling device; and using the thermal coupling device to couple thermal energy from the hot waste fluid to the first fluid prior to using the heater to heat the first fluid such that a thermal load on the heater is reduced.

Another aspect (20) includes the method of aspect (18), further including: providing a pre-heating tank on the input portion of the fluid supply system, the pre-heating tank being configured to store preheated first fluid; and selectively flowing pre-heated first fluid from the pre-heating tank to the heater such that a thermal load on the heater is reduced.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 is a fluid flow diagram for a semiconductor processing module which integrates a single-wafer cleaning chamber with a heat exchanger for recovery of thermal energy in accordance with one example embodiment of the present disclosure.

FIG. 2 is a fluid flow diagram for a semiconductor processing module which integrates a batch-wafer cleaning chamber with a heat exchanger for recovery of thermal energy in accordance with one example embodiment of the present disclosure.

FIG. 3 is a fluid flow diagram for a semiconductor processing module which integrates a single-wafer cleaning chamber with a heat exchanger and exchange tank for recovery of thermal energy in accordance with one example embodiment of the present disclosure.

FIG. 4 is a fluid flow diagram for a semiconductor processing module which integrates a batch-wafer cleaning chamber with a heat exchanger and for recovery of thermal energy in accordance with one example embodiment of the present disclosure.

FIG. 5 is a fluid flow diagram for a semiconductor processing module which integrates a single-wafer cleaning chamber with a heat exchanger and pre-heat tank for recovery of thermal energy in accordance with one example embodiment of the present disclosure.

FIG. 6 is a fluid flow diagram for a semiconductor processing module which integrates a batch-wafer cleaning chamber with a heat exchanger and pre-heat tank for recovery of thermal energy in accordance with one example embodiment of the present disclosure.

FIG. 7 and FIG. 8 are fluid flow diagrams for a semiconductor processing module which integrates a wafer cleaning chamber with a heat pump and heat exchangers for recovery of thermal energy in accordance with example embodiments of the present disclosure.

FIG. 9 and FIG. 10 are fluid flow diagrams for a semiconductor processing module which integrates a wafer cleaning chamber with a heat pump, heat exchangers, and storage tanks for recovery of thermal energy in accordance with example embodiments of the present disclosure.

FIG. 11 and FIG. 12 are fluid flow diagrams for a semiconductor processing module which integrates a wafer cleaning chamber with a heat pump, heat exchangers, and an exchange tank for recovery of thermal energy in accordance with example embodiments of the present disclosure.

FIG. 13 and FIG. 14 are fluid flow diagrams for a semiconductor processing module which integrates a wafer cleaning chamber with a heat pump, heat exchangers and a pre-heat tank for recovery of thermal energy in accordance with example embodiments of the present disclosure.

FIG. 15 and FIG. 16 are fluid flow diagrams for a semiconductor processing module which integrates a wafer cleaning chamber with a heat pump, heat exchangers and storage tanks for recovery of thermal energy in accordance with example embodiments of the present disclosure.

FIG. 17 and FIG. 18 are fluid flow diagrams for a semiconductor processing module which integrates a wafer cleaning chamber with a heat pump, heat exchangers, storage tanks, and a pre-heat tank, for recovery of thermal energy in accordance with example embodiments of the present disclosure.

FIG. 19 and FIG. 20 are fluid flow diagrams for a semiconductor processing module which integrates a wafer cleaning chamber with parallel heat pumps and heat exchangers for recovery of thermal energy in accordance with example embodiments of the present disclosure.

FIG. 21 and FIG. 22 are fluid flow diagrams for a semiconductor processing module which integrates a wafer cleaning chamber with parallel heat pumps, heat exchangers and storage tanks for recovery of thermal energy in accordance with example embodiments of the present disclosure.

FIG. 23 and FIG. 24 are fluid flow diagrams for a semiconductor processing module which integrates a wafer cleaning chamber with parallel heat pumps, heat exchangers and an exchange tank for recovery of thermal energy in accordance with example embodiments of the present disclosure.

FIG. 25 and FIG. 26 are fluid flow diagrams for a semiconductor processing module which integrates a wafer cleaning chamber with parallel heat pumps, heat exchangers and a pre-heat tank for recovery of thermal energy in accordance with example embodiments of the present disclosure.

FIG. 27 and FIG. 28 are fluid flow diagrams for a semiconductor processing module which integrates a wafer cleaning chamber with parallel heat pumps, heat exchangers and storage tanks for recovery of thermal energy in accordance with example embodiments of the present disclosure.

FIG. 29 and FIG. 30 are fluid flow diagrams for a semiconductor processing module which integrates a wafer cleaning chamber with parallel heat pumps, heat exchangers, storage tanks, and a pre-heat tank, for recovery of thermal energy in accordance with example embodiments of the present disclosure.

FIG. 31 is a fluid flow diagram for a semiconductor processing module which integrates a wafer cleaning chamber with series heat pumps for recovery of thermal energy in accordance with example embodiments of the present disclosure.

FIG. 32 is a fluid flow diagram for a semiconductor processing module which integrates a wafer cleaning chamber with cascaded heat pumps for recovery of thermal energy in accordance with example embodiments of the present disclosure.

FIG. 33 is a fluid flow diagram for a semiconductor processing module which integrates a wafer cleaning chamber with a combination of multiple heat pumps in series and in parallel for recovery of thermal energy in accordance with example embodiments of the present disclosure.

FIG. 34 is an example processing system that may be used as a controller for any of the processing modules of FIGS. 1-33 in accordance with example embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In one embodiment, a semiconductor processing chamber module may integrate heat exchangers (HE), heat pumps (HP), and other thermal storage (TS) devices with one or more chamber exhausts or effluent streams to exchange and repurpose heat for the same tool or another tool. Heat exchangers (HE) may improve energy efficiency for delivering heated chemicals compared with conventional heating methods. The total cost of ownership for equipment using the HE is lower, which potentially lowers the overall tool cost. The HE further reduces total energy consumption which allows fewer heaters to be used in the semiconductor processing chamber module, thereby, power usage is lowered. Integrating HE further promotes sustainability while reducing the cost of operating semiconductor processing chamber module.

In some examples, the semiconductor processing chamber module may perform wet processing operations including, but not limited to, wafer cleaning processes. The wet processing operations may encompass a range of wafer cleaning methodologies, including the cleaning of individual wafers (single-wafer cleaning), the simultaneous cleaning of a small group of wafers (mini-batch wafer cleaning), and the cleaning of a larger quantity of wafers processed together as a batch (batch wafer cleaning). Each approach may be selected based on specific process requirements, throughput goals, contamination control standards, and equipment capabilities within the semiconductor fabrication environment.

Semiconductor processing chamber module disclosed herein may implement one or more wafer cleaning processes. One example is sulfuric peroxide mixture (SPM) cleaning process which generally prepares wafers for subsequent processing steps. SPM cleaning is a wet cleaning processes in semiconductor manufacturing, designed to remove organic and some inorganic contaminants from silicon wafers, for example. SPM cleaning typically involves a mixture of sulfuric acid (H₂SO₄) and hydrogen peroxide (H₂O₂). SPM cleaning effectively strips photoresists and other residues. SPM cleaning may also hydroxylate the wafer surface for improved hydrophilicity.

Another example cleaning process is standard clean 1 (SC1) used in semiconductor wafer fabrication. SC1 is generally designed to remove organic contaminants and particles from the wafer surface before high-temperature processes like oxidation or diffusion. In one example, the SC1 solution is a base-peroxide mixture, typically made of 5 parts deionized water (DI), 1 part ammonium hydroxide (NH₄OH), and 1 part hydrogen peroxide (H₂O₂). This mixture may be heated to 75-80° C. and used for 10-15 minutes.

SPM cleaning and SC1 cleaning are compatible with (a) impregnated graphite, such as diabon, or similar materials to be used as HE plates; (b) polymers filled with thermally conductive fibers, particles, or materials such as graphite, carbon nanotubes, silicon carbide (SiC), or similar materials to be used as HE plates; (c) inert films such as amorphous silicon (a-Si), silicon nitride (SiN), or similar materials with coated metal parts, such as Tantalum, Hastelloy, stainless steel, gold, platinum, durimet, or similar materials to be used as HE plates; (d) inert fluoropolymer coatings, such as Ethylene Chlorotrifluoroethylene (Halar) coating, Ethylene Tetrafluoroethylene (ETFE) coating, Polytetrafluoroethylene (PTFE) coating, Fluorinated Ethylene Propylene (FEP) coating, or coated metal parts, such as Tantalum, Hastelloy, stainless steel, gold, platinum, durimet, or similar materials to be used as HE plates; (e) silicon carbide (SiC) HE plates; (f) Perfluoroalkoxy (PFA) HE plates; and (g) Tantalum, Hastelloy, stainless steel, gold, platinum, durimet, other compatible solid metal to be used as HE plates.

Yet another cleaning process is standard clean 2 (SC2) cleaning process used in semiconductor wafer fabrication. SC2 is designed to remove metallic or ionic contaminants from the wafer surface that may remain after the initial SC1 cleaning step, for example. In some examples, the SC2 solution is a hydrochloric peroxide mixture, typically made of 6 parts deionized water (DI), 1 part hydrochloric acid (HCl), and 1 part hydrogen peroxide (H₂O₂). This mixture may be heated to 75-80° C. and used for 10-15 minutes.

SC2 cleaning is compatible with (a) impregnated graphite, such as diabon, or similar materials to be used as HE plates; (b) polymers filled with thermally conductive fibers, particles, or materials such as graphite, carbon nanotubes, silicon carbide (SiC), or similar materials to be used as HE plates; (c) inert films such as amorphous silicon (a-Si), silicon nitride (SiN), or similar materials with coated metal parts, such as Tantalum, Hastelloy, gold, platinum, or similar materials to be used as HE plates; (d) inert fluoropolymer coatings, such as Ethylene Chlorotrifluoroethylene (Halar) coating, Ethylene Tetrafluoroethylene (ETFE) coating, Polytetrafluoroethylene (PTFE) coating, Fluorinated Ethylene Propylene (FEP) coating, or coated metal parts, such as Tantalum, Hastelloy, gold, platinum, or similar materials to be used as HE plates; (e) silicon carbide (SiC) HE plates; (f) Perfluoroalkoxy (PFA) HE plates; and (g) Tantalum, Hastelloy, gold, platinum, other compatible solid metal to be used as HE plates.

Still another cleaning process is phosphoric acid cleaning, which is a widely used in both industrial and semiconductor contexts for removing rust, mineral deposits, scale, and hard water stains. Phosphoric acid cleaning uses a mild mineral acid (H₃PO₄), which is safer than stronger acids like hydrochloric or sulfuric acid. Phosphoric acid cleaning may be used in oxide etching for compound semiconductors (e.g., GaAs), or surface preparation in wafer processes.

Embodiments disclosed herein provide one or more thermal collection and transfer technologies with one or more semiconductor processing chamber modules may be used to repurpose heat from wastewater or chemicals in semiconductor manufacturing processes such as the cleaning processes described above. The technologies featured in these embodiments include (a) a heat exchanger (HE) and a heat pump (HP) that drive efficiency when delivering heated chemical compared with conventional heating methods and reduce energy consumption which allows lower power consumption and fewer conventional heaters in the semiconductor processing chamber modules, (b) multi-heat pumps arranged in parallel (MHPP) to increase capacity, (c) multi-heat pumps arranged in series (MHPS) to increase efficiency and improve the coefficient of performance (CoP), (d) multi-heat pumps arranged in cascade (MHPC) that enables a higher temperature lift from source-to-load, (f) multi-heat pumps arranged in a combination of parallel, series and cascade to increase capacity of the heated fluid volume, increase efficiency and coefficient of performance, and enable higher temperature lift from source-to-load, (g) thermal storages (TS) to decrease or eliminate cycle times for heat pumps (HP) and enable asynchronous flow volumes of supply and thermal source fluids (HE/HP), (h) a thermal storage resistance heater (TSRH) to decrease or eliminate cycle times for heat pumps (HP), which enables asynchronous flow volumes of supply and thermal source fluids (HE/HP), and guarantees process temperature in heat pump arrangement, (i) an exchange tank (ET) to allow for storage of thermal energy for asynchronous operation between draining and filling of process fluid to the tank, and (j) a pre-heat tank (PT) to allow for storage of thermal energy for asynchronous operation between draining and filling of process fluid to the pre-heat tank.

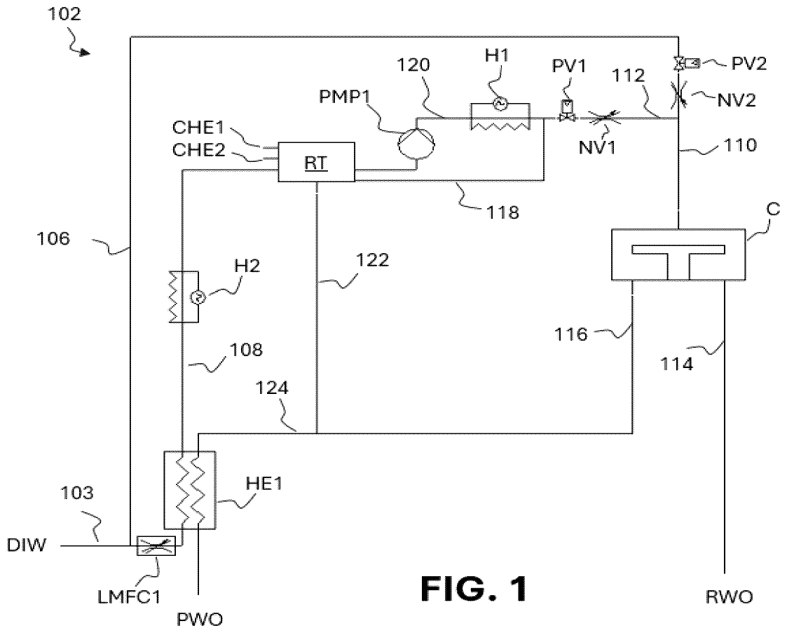

FIG. 1 is a fluid flow diagram for a semiconductor processing module which integrates a single-wafer cleaning chamber with a heat exchanger for recovery of thermal energy in accordance with one example embodiment of the present disclosure. The semiconductor processing module 102 is designed to manage the delivery and thermal control of cleaning chemistries and rinse water for single wafer processing.

In the example embodiment of FIG. 1, deionized water (DIW) is input through line 103, which branches into two separate paths. One path is routed to a liquid mass flow controller LMFC1, allowing for regulation of DIW entering the chemical processing system. The other path 106 is dedicated to the rinse functionality of the system. This rinse line 106 passes through a pneumatic valve PV2 and a needle valve NV2, which controls the flow rate and pressure of the DIW before it is delivered to the chamber C through line 110. The chamber C may be implemented as a spin chamber used to perform wafer cleaning, rinsing and possibly drying processes on a single wafer. For example, one or more of the SPM, SC1, SC2, and phosphoric acid cleaning may be implemented by the module 102.

Returning to input line 103, DIW flow from the LMFC1 continues through heat exchanger HE1 where its temperature may be passively increased by thermal exchange, depending on system conditions. Inline heater H2 then raises the temperature of the DI water as needed. After heating, the water enters the recirculation tank RT, where it can be combined with two chemical inputs, CHE1 and CHE2. These chemicals, when mixed with DIW, form cleaning solutions such as SC1, SC2, or other dilute chemistries required for wafer surface preparation, as discussed above. The recirculation tank RT serves as a mixing reservoir and thermal regulation tank for the cleaning fluid. RT may be periodically drained and recharged.

The fluid within the RT is drawn into a circulation loop through a line 120, where it passes through pump PMP1 which maintains flow pressure, and then through a second heater H1, which further adjusts the temperature of the cleaning solution to meet process requirements. After passing through H1, the fluid continues through return line 118, which returns it to the recirculation tank RT, allowing for continuous mixing and thermal stabilization.

At a junction between heater H1 and the return line 118, a portion of the heated fluid may be diverted through line 112. This diverted stream passes through a second pneumatic valve PV1 and a second needle valve NV1, which controls flow of the cleaning solution toward the spin chamber. The cleaning fluid is then delivered into the spin chamber C through the same delivery line used for the DIW rinse, line 110. In some embodiments, the recirculation tank RT can be configured to supply a processing solution to two or more processing chambers such as the spin chamber. A back pressure valve may be included on line 118 to maintain pressure to the chambers regardless of how many chambers may be demanding flow. A controller controls actuation of PV1, PV2, NV1, and NV2 to determine the type of fluid delivered through 110 at any given time.

From the spin chamber, used fluids exit through two separate paths. Line 114 directs spent rinse water to the rinse water outlet (RWO), and line 116 handles any fluid associated with chemical processes and directs it through heat exchanger HE1 to the process waste outlet PWO. Additionally, the recirculation tank is equipped with a dedicated drain line, line 122, which also connects to the process waste outlet via HE1. Lines 114, 116 and/or 122 may include any suitable flow valve for controlling flow to common line 124. In some embodiments, one or more temperature sensors and flow valves may be used to ensure that hot waste is sent to the heat exchanger HE1 and cold waste will bypass HE1 and drain from the system. The line 124 may convey a thermally energized liquid into the heat exchanger HE1, where heat transfer occurs. Consequently, the DIW passing through line 108 in HE1 may absorb thermal energy from the liquid passing through line 124 through HE1 thereby reducing the load on heater H2.

The integration of HE may improve energy efficiency by exchanging the heat between liquid in lines 124, 108 inside HE1. This reduces the total cost of ownership of module 102 relative to conventional methods which use in-line heaters H1 and H2 alone, which potentially lowers the overall tool cost. The heat exchanger HE1 further reduces total energy consumption which allows fewer heaters to be used in the semiconductor processing chamber module, thereby lowering power usage by the module 102.

In some embodiments, the heat exchanger HE1 in FIG. 1 may be substituted by a thermal storage and heat exchanger unit (TS/HE). The TS/HE unit may include a heat exchanger and a thermal storage (TS) having a thermal storage resistance heater (TSRH) therein. The benefits of using the heat exchanger are similar to the benefits described above with respect to H1. Additionally, using the TS and TSRH enables asynchronous flow volumes of supply and thermal source fluids. Use of the TSRH also facilitates maintenance process temperatures in various heat pump arrangements.

A controller (not shown) can coordinate the operation of all system components including flow valves, temperature sensors, recirculation tank RT and processing chamber C, for example. The controller can be connected to or included within the semiconductor processing module 102 or located remotely but in communication with the module 102. The controller may be coupled to various components of the module 102 to receive inputs from and provide outputs to the various components. For example, the controller can be configured to receive fluid temperature readings from one or more temperature sensors and control actuation of one or more flow valves to manage fluid flow for increasing recovery of otherwise lost thermal energy within the module. Additionally, a controller may be connected to a corresponding memory storage unit and user interface (not shown). Various tool operations can be executed via the user interface, and various processing recipes and operations can be stored in a storage unit. Accordingly, a given substrate can be processed within the chamber C with various microfabrication techniques.

The controller may include one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a proscribed plasma process recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

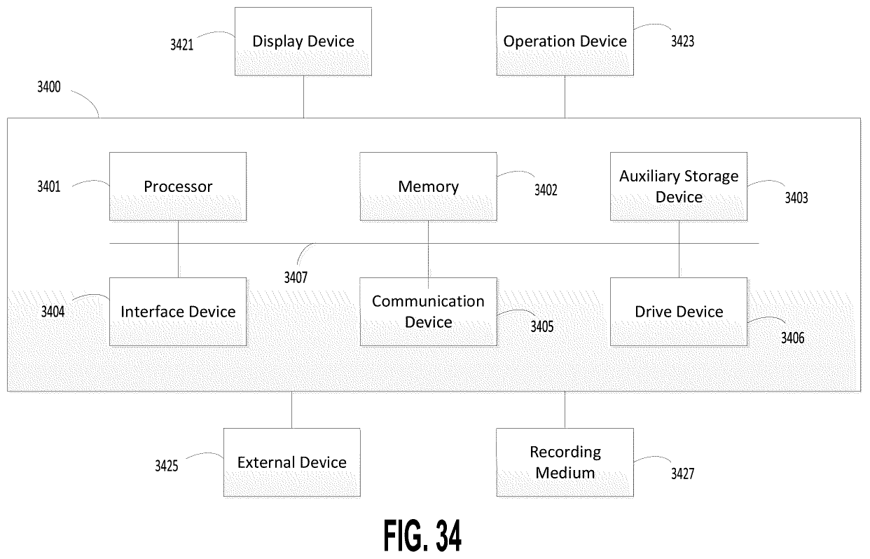

The controller may be implemented as, or perform functions in cooperation with, an information processing device such as the device 3400 of FIG. 34 described below.

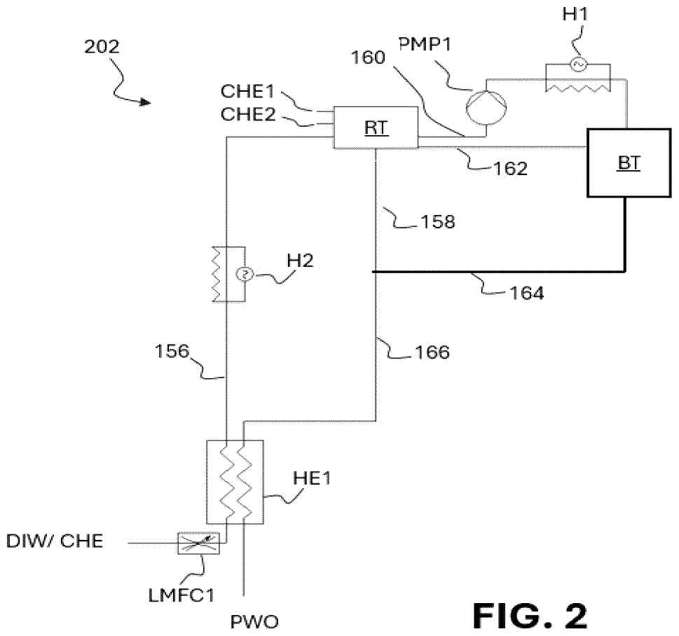

FIG. 2 is a fluid flow diagram for a semiconductor processing module which integrates a batch-wafer cleaning chamber with a heat exchanger for recovery of thermal energy in accordance with one example embodiment of the present disclosure. The semiconductor processing module 202 is designed to manage the delivery and thermal control of cleaning chemistries and rinse water for batch wafer processing.

In the example of FIG. 2, the module 202 accepts an input of either deionized water (DIW) or process chemicals CHE at a relatively low temperature, typically around 20 degrees Celsius. This fluid enters the system and flows through line 156, which is connected to liquid mass flow controller LMFC1 for flow regulation. From LMFC1, the fluid continues through the integrated heat exchanger HE1, where its temperature may be passively increased by thermal exchange, depending on system conditions.

After passing through the heat exchanger, the fluid is routed through an inline heater H2 to reach the target temperature required for the cleaning process. The heated fluid then enters the recirculation tank RT, where it can be mixed with chemical inputs CHE1 and CHE2 to form a solution suitable for wafer cleaning, for example. The solution from the recirculation tank is directed through line 160 to a circulation loop which includes pump PMP1 and a secondary inline heater H1. The pump maintains flow rate and pressure, while heater H1 ensures final temperature adjustment before the solution enters the batch wafer tank BT, where multiple wafers are cleaned simultaneously. For example, one or more of the SPM, SC1, SC2, and phosphoric acid cleaning discussed above may be implemented by the module 202. Line 162 provides a direct fluid path between the RT and the BT, allowing for controlled delivery and recirculation of the cleaning solution. Within the batch tank BT, additional valves may be incorporated to manage fluid distribution, supply, and return as needed during processing. In some embodiments, the recirculation tank RT can be configured to supply a processing solution to two or more processing chambers such as the batch tank BT.

To manage waste, the module 202 includes two waste outlet lines 158 and 164. Line 158 drains fluid from the recirculation tank, while line 164 drains used fluid from the batch tank. Each line can be equipped with flow control valves and may be routed to a shared line 166 which enters the heat exchanger HE1. The fluid in line 166 typically retains a higher temperature after being used in the cleaning process. As it passes through the heat exchanger, it transfers thermal energy to the incoming, cooler fluid in line 156. This passive heat exchange process improves system efficiency by pre-warming incoming DIW or chemicals, thereby reducing the energy load on heater H2. After releasing its residual heat, the fluid in line 166 is then discharged to the process waste outlet (PWO).

The integration of HE1 may improve energy efficiency by exchanging the heat between the lines 156, 166 in the HE. The total cost of ownership of a system using heaters H1 and H2 is lower with HE1, which potentially lowers the overall tool cost. The heat exchanger HE1 further reduces total energy consumption by H1 and H2 which allows fewer heaters to be used in the semiconductor processing chamber module, thereby, power usage is lowered.

In some embodiments, the heat exchanger HE1 in FIG. 2 may be substituted by a thermal storage and heat exchanger unit TS/HE. The TS/HE unit may include a heat exchanger and a thermal storage (TS) having a thermal storage resistance heater (TSRH) therein. The benefits of using the HE are similar to the benefits described above. Additionally, using the TS and TSRH enables asynchronous flow volumes of supply and thermal source fluids. Use of the TSRH also facilitates maintenance process temperatures in various heat pump arrangements.

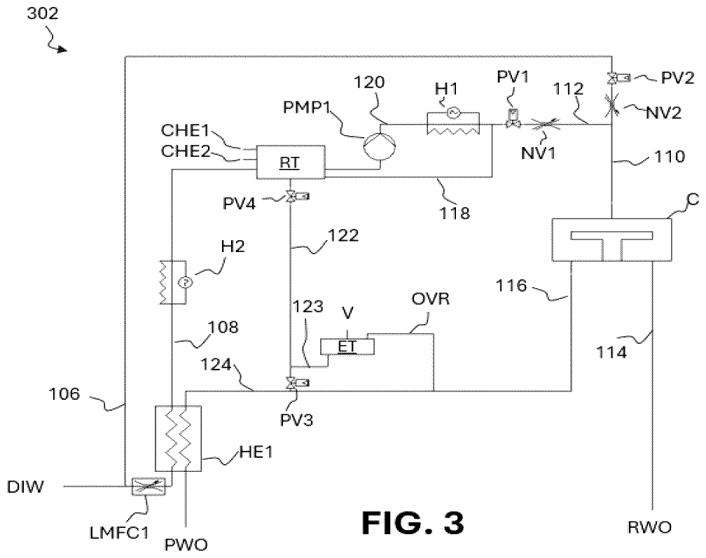

FIG. 3 is a fluid flow diagram for a semiconductor processing module which integrates a single-wafer cleaning chamber with a heat exchanger and exchange tank for recovery of thermal energy in accordance with one example embodiment of the present disclosure. The module 302 illustrated in FIG. 3 includes similar components as those depicted in FIG. 1 but adds an exchange tank ET for collecting waste cleaning solution from RT.

In the example embodiment shown, line 122 from RT includes PV3 and PV4 which are series connected to isolate a branch line 123 leading to exchange tank ET. A controller actuates PV3 and PV4 to control filling of the exchange tank and draining of its contents through the heat exchanger HE1 to the process waste output PWO. In the illustrated embodiment, overflow line OVR sends overflow from ET to waste line 116 of the spin chamber as shown. The exchange tank is also provided with a vent V. As noted above, recirculation tank RT may be periodically drained and recharged. In one example, the exchange tank ET functions as a thermal storage of waste process solution from the recirculation tank so that it may be drained through the heat exchanger at an optimal time for recovery of thermal energy to reduce the load of in-line heater H1 and H2, for example. The ET allows storing the thermal energy for asynchronous operation between draining and filling of any hot fluid in the semiconductor process chamber C or the RT.

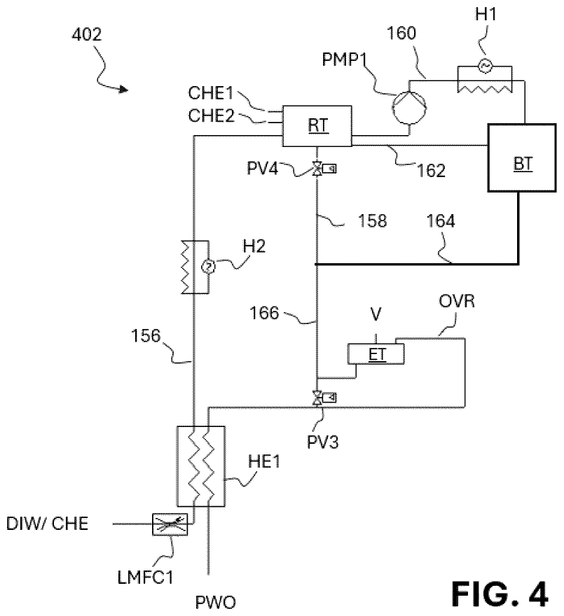

FIG. 4 is a fluid flow diagram for a semiconductor processing module which integrates a batch-wafer cleaning chamber with a heat exchanger and for recovery of thermal energy in accordance with one example embodiment of the present disclosure. The semiconductor processing chamber module illustrated in FIG. 4 includes similar components to those depicted in FIG. 2 but adds an exchange tank ET. In the embodiment shown, the exchange tank ET is provided in parallel with line 166. Pneumatic valves PV3 and PV4 are provided on line 166 and 158 respectively, and may be actuated by a controller. In some embodiments, line 170 may be provided to make use of the overflow OVR. The benefits of using the ET in module 402 are similar to those described above in FIG. 3.

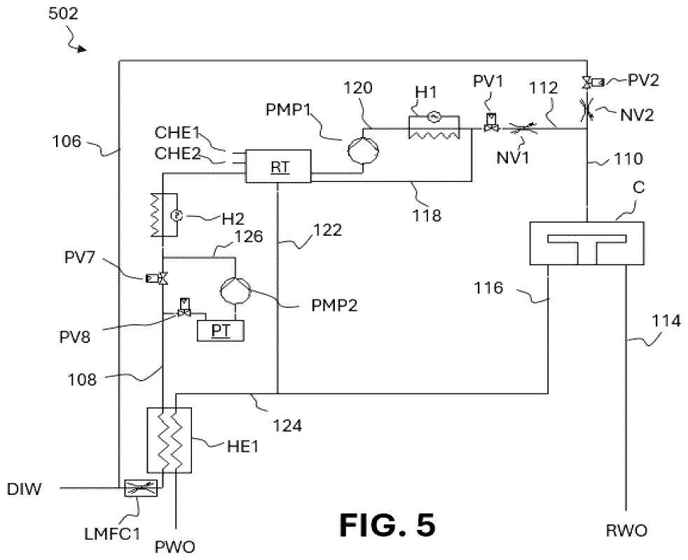

FIG. 5 is a fluid flow diagram for a semiconductor processing module which integrates a single-wafer cleaning chamber with a heat exchanger and pre-heat tank for recovery of thermal energy in accordance with one example embodiment of the present disclosure. The semiconductor processing module 502 illustrated in FIG. 5 includes similar components to those depicted in FIG. 1, but adds a pre-heat tank PT, pump PMP2, pneumatic valve PV7, and pneumatic valve PV8. As shown, pre-heat tank PT is provided between heat exchanger HE1 and in-lie heater H2, and in parallel with line 108. A controller may actuate PV7 and PV8 to control the timing and amount of DIW into and out of the pre-heat tank. The pre-heat tank PT allows the liquid in line 108 to be stored, so that the liquid may rise to a set point before it enters the recirculation tank RT. This reduces the time needed to reach reaction temperature and reduces loss of thermal energy before it reaches the RT and maintains throughput of the processing module. In one example embodiment, the pre-heat tank PT can be used to recover thermal energy during emptying and refill of the recirculation tank RT. For example, where RT must be emptied before refilling, the spent solution can be drained through HE1 while DIW is supplied to fill PT.

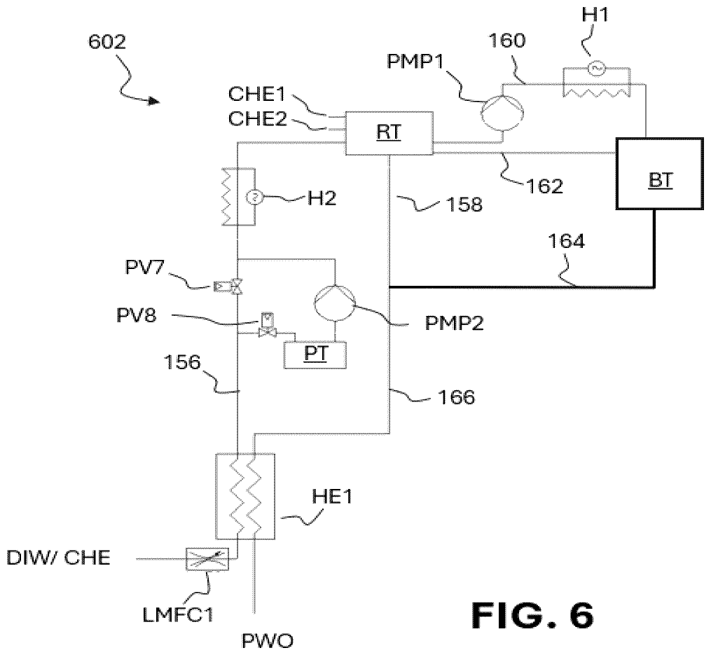

FIG. 6 is a fluid flow diagram for a semiconductor processing module which integrates a batch-wafer cleaning chamber with a heat exchanger and pre-heat tank for recovery of thermal energy in accordance with one example embodiment of the present disclosure. The semiconductor processing module 602 illustrated in FIG. 6 includes similar components to those depicted in FIG. 2, but provides adds PT, PMP3, PV7, and PV8. As shown, the pre-heat tank PT is added in parallel to line 156. The benefits of using the PT are similar to those described above in FIG. 5.

In some embodiments, the heat exchanger HE1 in any one of FIGS. 3-6 may be replaced with a thermal storage and heat exchanger unit (TS/HE). The TS/HE may include a heat exchanger and a thermal storage (TS) having a thermal storage resistance heater (TSRH) therein. The benefits of using the HE are similar to the benefits described above. Additionally, using the TS and TSRH enables asynchronous flow volumes of supply and thermal source fluids. Use of the TSRH also facilitates maintenance process temperatures in various heat pump arrangements.

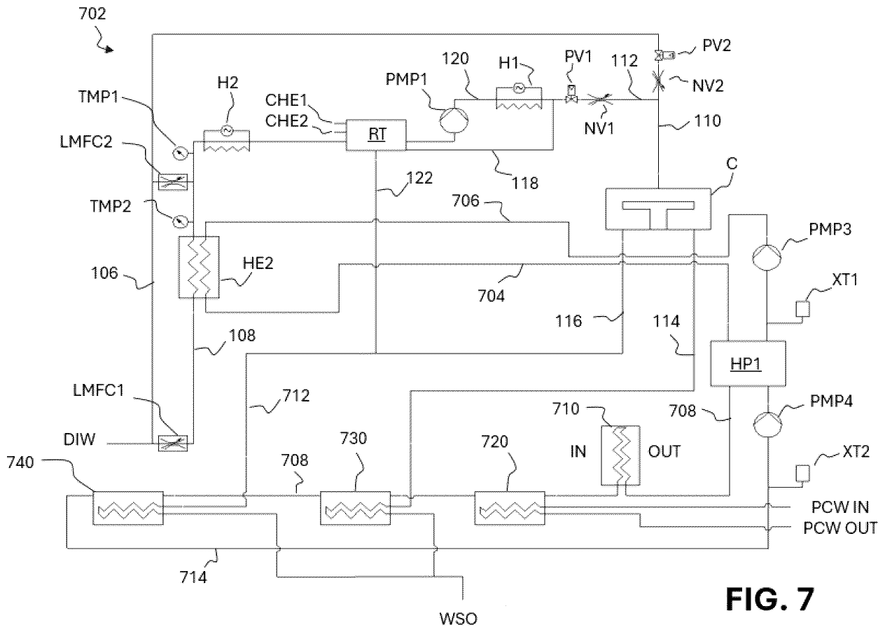

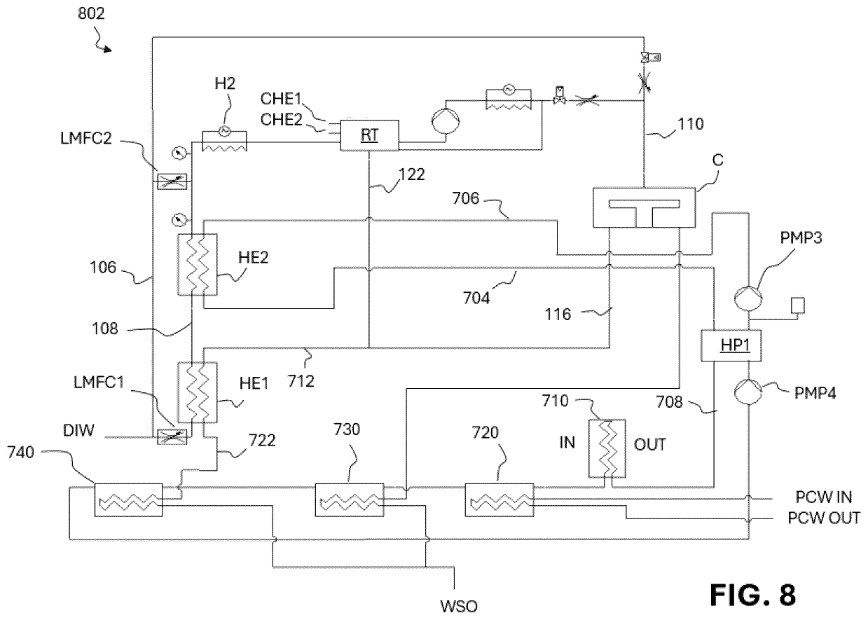

In some embodiments, one or more heat pumps may be used to recover thermal energy from one or more systems for use in a semiconductor manufacturing process such as a cleaning process. FIG. 7 and FIG. 8 are fluid flow diagrams for a semiconductor processing module which integrates a wafer cleaning chamber with a heat pump and heat exchangers for recovery of thermal energy in accordance with example embodiments of the present disclosure. The semiconductor processing module 702 illustrated in FIG. 7 is similar to the configuration depicted in FIG. 1 but has heat pump HP1 integrated therein to collect thermal energy from various components and transfer the collected energy to heat exchanger HE2 for recovery by the semiconductor cleaning process.

Specifically, fluid heated by the heat pump HP1 exits through the line connected to pump PMP3 and flows through line 706 to HE2, where it releases thermal energy to line 108 carrying DIW which is mixed in the RT as described above. In the embodiment of FIG. 7, an additional flow controller LMFC2 connects the unheated DIW line 106 with the heated DIW line 108. Temperature sensors TMP1 and TMP2 provide temperature readings to a controller which controls LMFC2 to flow ambient DIW into line 108 as an additional means of temperature control. After passing through HE2, fluid from the heat pump continues through line 704 and returns to the heat pump HP1 completing a high-temperature circulation (i.e., load) loop of the heat pump. An expansion tank XT1 may be connected to a branch of the line between PMP3 and HP1 to accommodate thermal expansion in this loop, for example.

On a low-temperature side of the heat pump, line 708 carries cooled fluid from the heat pump and distributes it through a series of heat exchangers that collect waste heat from different subsystems in the module and/or fab. Specifically, air heat exchanger (Air HE) 710 is connected to line 708 on one side and receives airflow from a tool exhaust IN and discharges it to a tool exhaust OUT, transferring the air's heat into the circulation fluid within Air HE 710. From the Air HE 710, the fluid travels along line 708 through Process Cooling Heat Exchanger (Process Cooling HE) 720, then the Drain Cooling Heat Exchanger (Drain Cooling HE) 730, and finally the Waste Heat Exchanger (Waste HE) 740. As shown, each of these heat exchangers include separate internal fluid loops, through which they absorb heat from corresponding waste or process sources into the main circulation stream.

Specifically, in the embodiment of FIG. 7, Process Cooling HE 720 includes process cooling water in (PCW IN) and process cooling water out (PCW OUT) as shown. Rinse drain line 114 from the chamber C flows into the Drain Cooling HE 730. Process solution drain line 116 from the spin chamber and process solution drain line 122 from the rinse tank RT converge into a common line 712, which flows into Waste HE 740. The Drain Cooling HE 730 and Waste HE 740 collect thermal energy from waste fluids. Output lines from these two heat exchangers combine into a common waste stream output WSO, which is used to drain the now-cooled liquid waste out of the system. The order of the heat exchangers in FIG. 7 may be changed based on the temperature of the different sources. For example, in some embodiments flow valves and temperature sensors may be incorporated into the flow system and a controller may use temperature readings to control the valves to ensure that heat is collected from the coldest source first and collected from additional sources in order of temperature increase. Bypass valves can be added and controlled by a controller and/or specific HE components may be excluded or organized in parallel.

After the Waste HE 740, fluid is routed back to the heat pump through line 714. This return line includes pump PMP4 between the Waste HE 740 and the heat pump HP1, ensuring continuous flow. An expansion tank XT2 may be connected to a branch line off of line 714 to manage fluid volume changes due to temperature fluctuations in the loop, for example. Thus, cold side loop of HP1 collects heat from Air HE 710, Process Cooling HE 720, Drain Cooling HE 730, and Waste HE 740 to reduce the thermal load of the heat pump.

Fluids circulating from the HP1 may be a heat transfer fluid, a refrigerant, or any fluid suitable for system operating conditions. The use of the heat pump HP1 in the semiconductor processing chamber module offers sustainability benefits. The addition of the heat pump provides a more energy-efficient (and reduced CO₂ emissions) method of delivering heated chemicals compared to conventional approaches. It also contributes to a lower initial investment, lower total cost of ownership (TCO) and reduced tool cost by decreasing energy consumption, which enables the use of lower-power, smaller, or fewer conventional heaters.

The module 802 illustrated in FIG. 8 includes heat pump HP which collects heat from Air HE 710, Process Cooling HE 720, Drain Cooling HE 730, and Waste HE 740 and transfers the collected heat to heat exchanger HE2 as described in FIG. 7 above but provides an additional heat exchanger HE1 for transferring thermal energy to input DIW. Specifically, in the embodiment of FIG. 8, heat exchanger HE1 is provided on DIW input line 108 in series with heat exchanger HE2. Process solution drain line 116 from the spin chamber and process solution drain line 122 from the rinse tank RT converge into a common line 712, which flows into HE1 to transfer thermal energy to the DIW within the exchanger HE1. An output drain from HE1 feeds fluid line 722 which connects to Waste HE 740. Thus, HE1 provides a passive energy source to DIW thereby reducing thermal load of active heaters of the module, and further delivers the waste to Waste HE 740 coupled to the cold side loop of HP1 to improve efficiency of the heat pump.

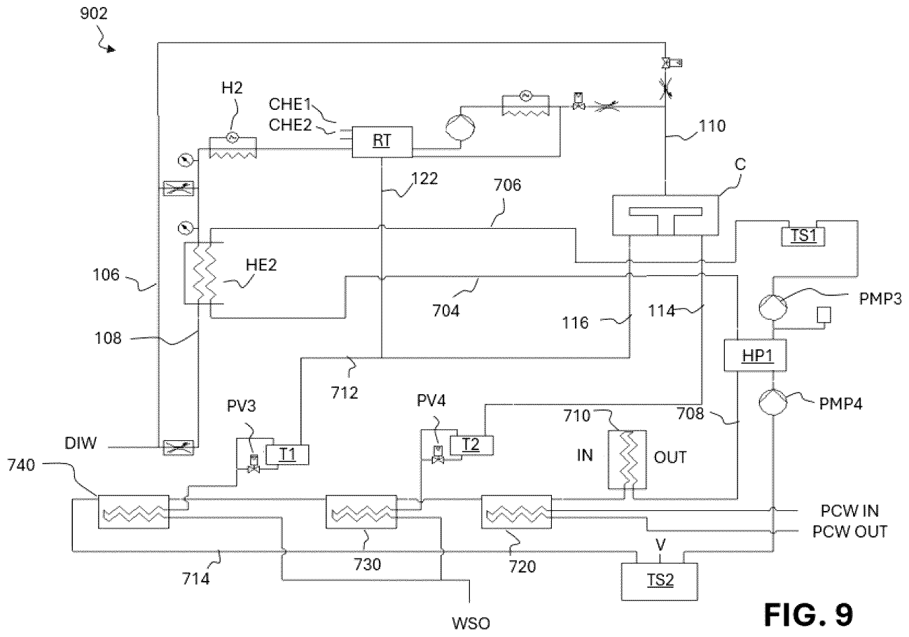

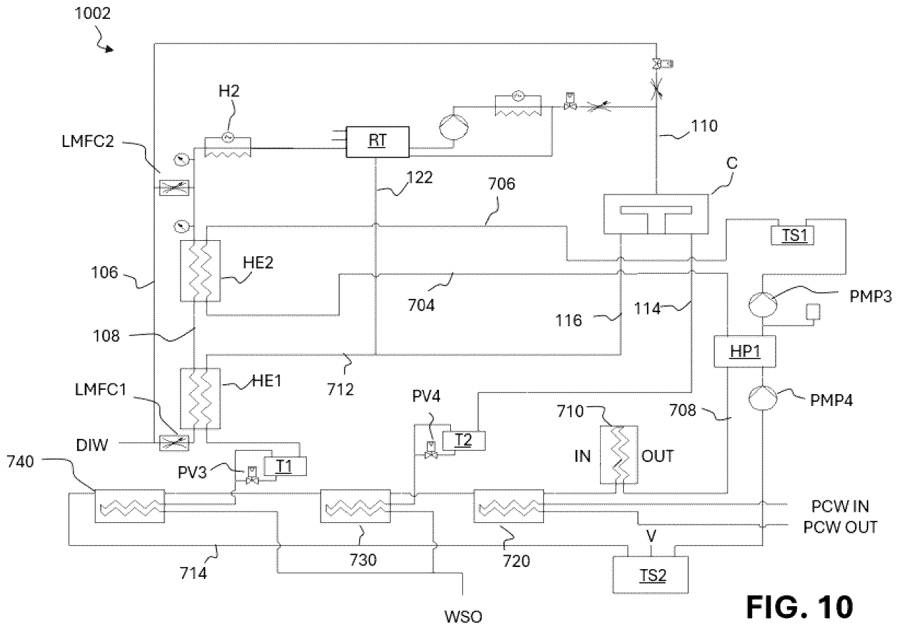

Additional fluid storage tanks, including thermal storage tanks, may be used to facilitate recovery of thermal energy in the semiconductor processing module. FIG. 9 and FIG. 10 are fluid flow diagrams for a semiconductor processing module which integrates a wafer cleaning chamber with a heat pump, heat exchangers, and storage tanks for recovery of thermal energy in accordance with example embodiments of the present disclosure. The semiconductor processing module 902 includes heat pump HP1 which collects heat from Air HE 710, Process Cooling HE 720, Drain Cooling HE 730, and Waste HE 740 and transfers the collected heat to heat exchanger HE2 as described in FIG. 7 above, but integrates additional storage tanks T1 and T2, and thermal storage tanks TS1 and TS2.

Specifically, storage tank T1 and pneumatic valve PV3 are included on line 712 which provides hot process waste from the recirculation tank RT and cleaning chamber C. Similarly, storage tank T2 and pneumatic valve PV4 are included on line 114 which provides rinse waste from the chamber. Tanks T1 and T2 do not include an active heat source but serve as passive heat storage tanks for waste drained from the RT and chamber. A controller activates PV3 and PV4 to control storage and flow of the waste fluids for optimal recovery of thermal energy by the cold side loop of HP1. In addition to helping to regulate the timing of waste and supply flows, in some embodiments tank T1 can facilitate the dumping of the recirculation tank RT and stores heated waste for the refill cycle.

In the example embodiment of FIG. 9, thermal storage TS1 is provided on fluid line 706 of the hot side loop of the heat pump, and thermal storage TS2 is provided on line 714 of the cold side loop of the heat pump HP1. TS1 and TS2 each include thermal storage resistance heaters (TSRH) for actively heating fluids stored therein. As such TS1 and TS2 actively heat fluids of the hot side loop and cold side loop of HP1 to maintain process throughput and improve efficiency of the processing module. In some embodiments, TS1 and TS2 may not include any active heating mechanism and may incorporate a phase change material, for example. In one example, TS2 may be used to allow HP1 to continue to run when the system hits short idle cycles. On/Off cycles increase wear on heat pumps and they can take several minutes to deliver at power when turned on again, which can reduce through put. TS1 can be implemented as a large water/fluid tank, a phase change storage device or other thermal storage unit. In yet another example, TS1 and/or TS2 may include both a phase change material and a heating element.

The semiconductor processing module 1002 illustrated in FIG. 10 includes similar components to those depicted in FIG. 9 but includes heat exchanger HE1 on DIW line 108 in series with heat exchanger HE2. Hot waste in line 712 flows into HE1 to transfer energy to the input DIW, and exits HE1 into line 722 as discussed above.

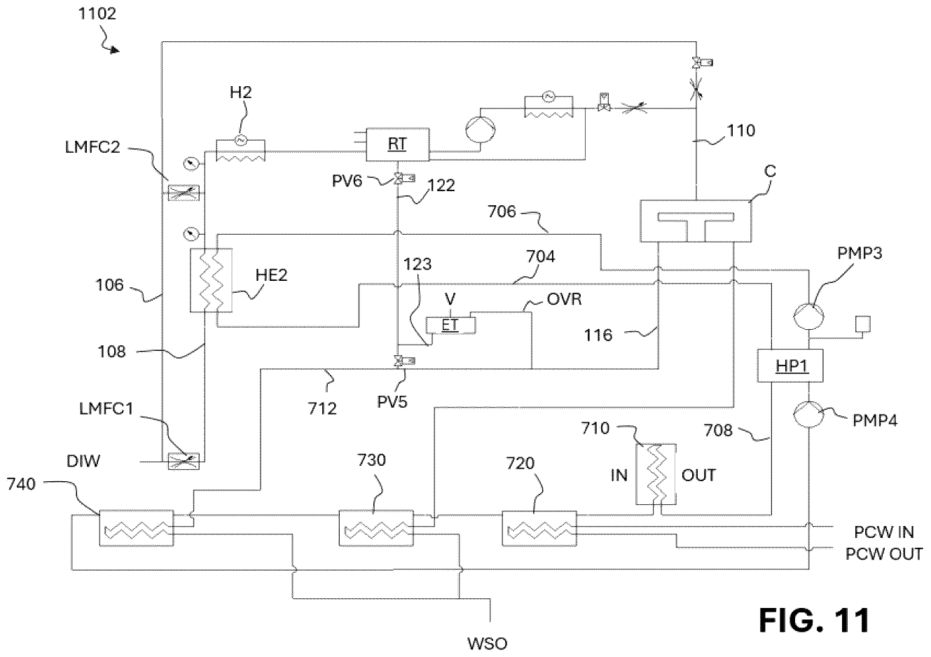

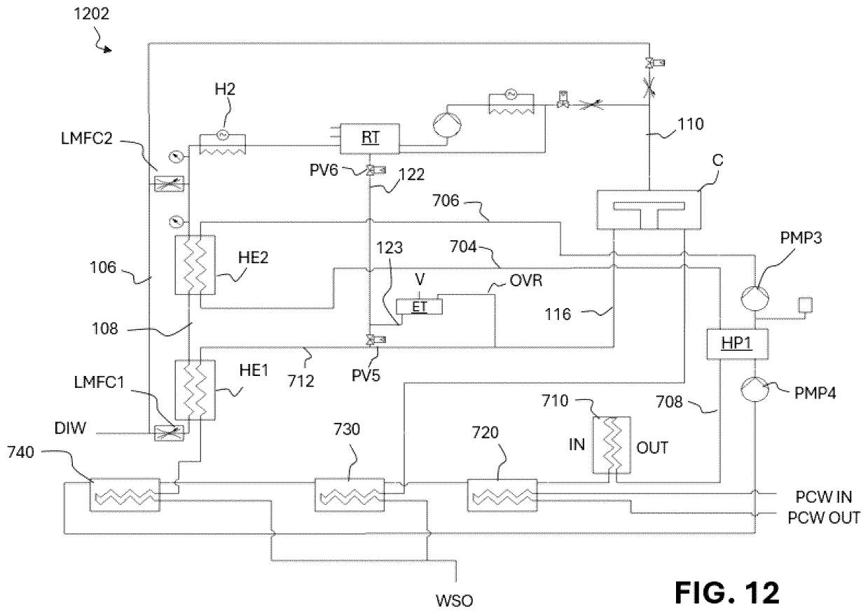

An exchange tank may also facilitate recovery of thermal energy in a heat pump flow system. FIG. 11 and FIG. 12 are fluid flow diagrams for a semiconductor processing module which integrates a wafer cleaning chamber with a heat pump, heat exchangers, and an exchange tank in accordance with example embodiments of the present disclosure. The semiconductor processing chamber module 1102 illustrated in FIG. 11 includes similar components to those depicted in FIG. 7 and adds exchange rank (ET) with a 40-liter capacity (for example).

As shown, the module 1102 provides ET between line 116 which carries process waste from the chamber C, and line 122 which carries spent cleaning solution from RT. Pneumatic valves PV5 and PV6 are provided on drain line 122 from the recirculation tank, and branch line 123 extends from line 122 between the pneumatic valves. PV5 and PV6 are controlled by a controller to regulate the volume and timing of hot waste into and out of the exchange tank. In one example, PV6 is opened and PV5 is kept closed to drain spent cleaning solution from RT into to exchange tank so that the RT can be replenished with fresh cleaning solution suitable for a wafer cleaning process in chamber C. The spent cleaning solution is stored in ET until PV5 is opened to drain the solution through line 712 into the exchanger 740 at an optimal time for recovery of thermal energy from the spent solution.

The semiconductor processing module 1202 illustrated in FIG. 12 includes similar components to those depicted in FIG. 11 and adds heat exchanger HE1 on DIW input line 108 in series with heat exchanger HE2. Pneumatic valves PV5 and PV6 may be controlled by a controller to fill and drain the exchange tank ET, as discussed above, at optimal times for thermal transfer to DIW for mixing in recirculation tank RT. Output of HE1 further supplies Waste HE 740 to couple thermal energy to the cold side loop of HP1 thereby reducing the load on HP1.

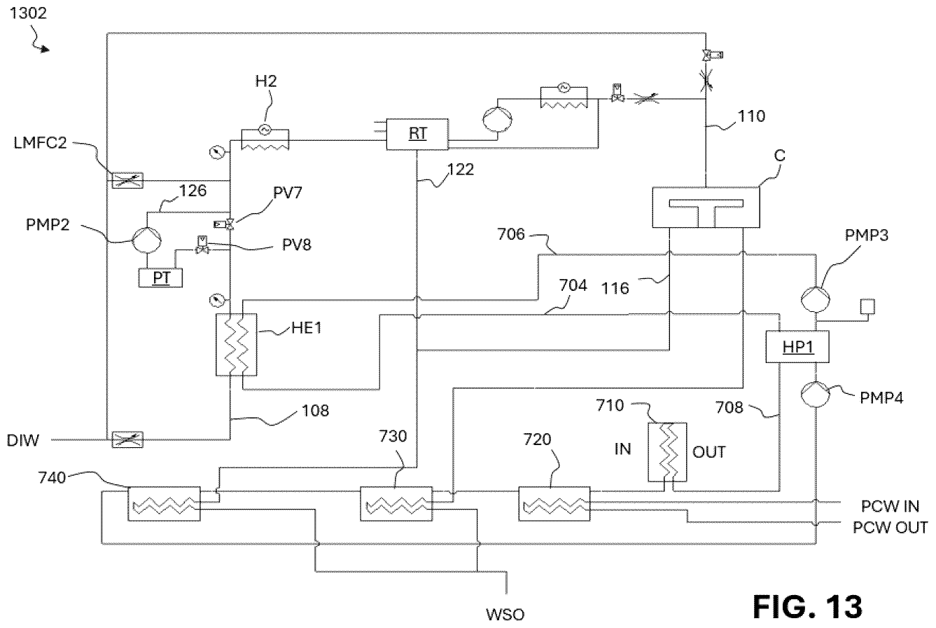

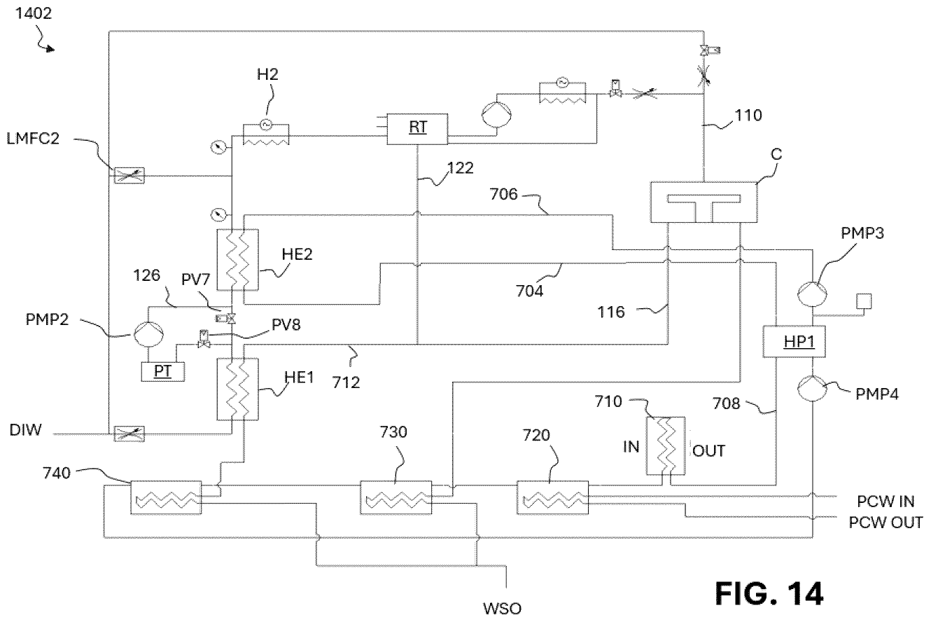

A heat pump flow system may also include a pre-heat tank to facilitate energy recovery in the system. FIG. 13 and FIG. 14 are fluid flow diagrams for a semiconductor processing module which integrates a wafer cleaning chamber with a heat pump, heat exchangers and a pre-heat tank for recovery of thermal energy in accordance with example embodiments of the present disclosure. The semiconductor processing module 1302 illustrated in FIG. 13 includes similar components to those depicted in FIG. 7 with the addition of pre-heat tank PT.

As shown pre-heat tank PT is provided in parallel with heated DIW line 108 down stream of HE1. Pump PMP2, and pneumatic valves PV7 and PV8 work under command of a controller to fill PT for pre-heating and supply pre-heated DIW to the recirculation tank RT as discussed above. Thus, PT, PMP2 and PV7 and PV8 collect and actively preheat the DIW, and supply the heated DIW at optimal times for maintaining throughput of the cleaning module while reducing the thermal load on in-line heaters of the system.

The semiconductor processing chamber module 1402 illustrated in FIG. 14 includes similar components to those depicted in FIG. 13 but adds heat exchanger HE1 on DIW input line 108. As such, the preheat tank PT, pump PMP2, and pneumatic valves PV7 and PV8 are provided in parallel to line 108 between HE1 and HE2. PT, PMP2, PV7 and PV8 are controlled by a controller to draw fluid from, and supply pre-heated fluid to, line 108 between HE1 and HE2 as discussed above. Output of HE1 further supplies Waste HE 740 to couple thermal energy to the cold side loop of HP1 as also discussed

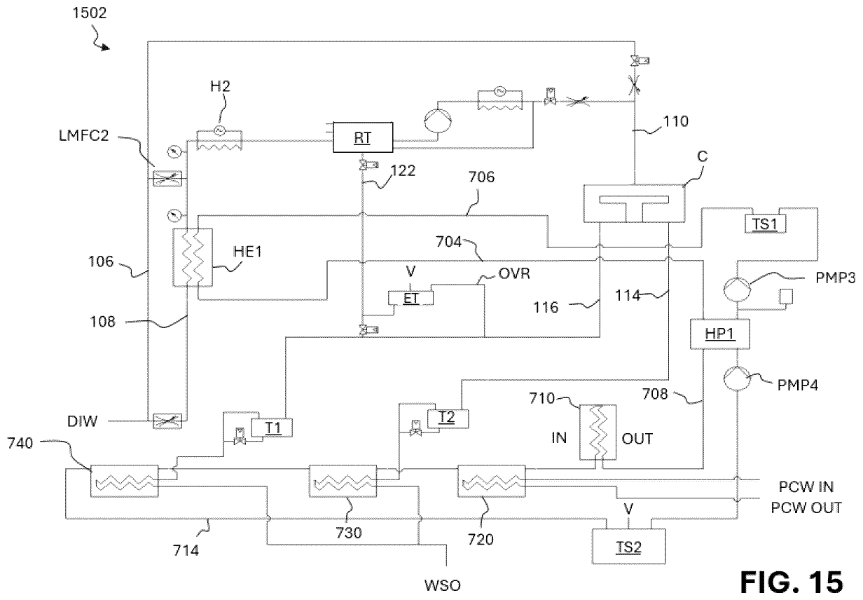

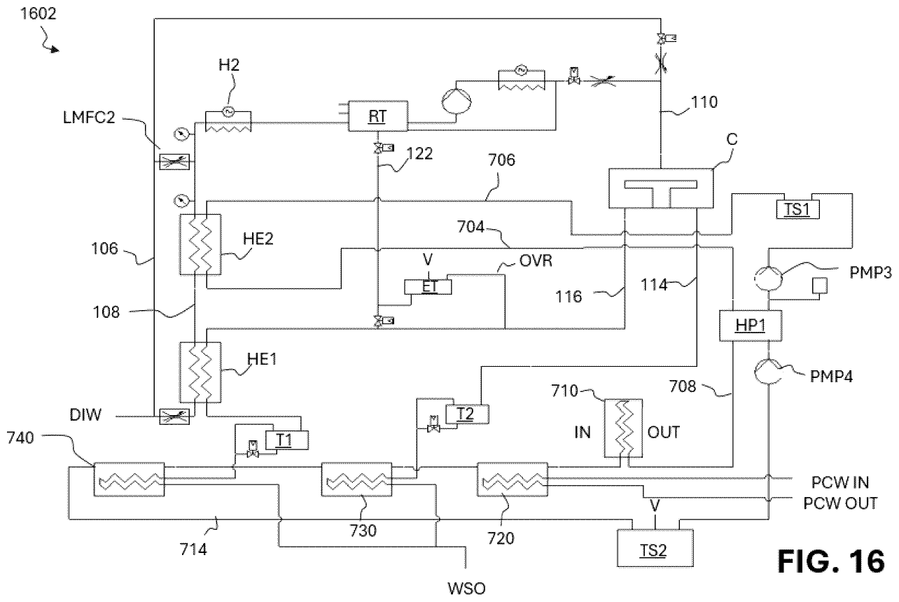

FIG. 15 and FIG. 16 are fluid flow diagrams for a semiconductor processing module which integrates a wafer cleaning chamber with a heat pump, heat exchangers, an exchange tank and storage tanks for recovery of thermal energy in accordance with example embodiments of the present disclosure. The semiconductor processing module 1502 illustrated in FIG. 15 includes similar components to those depicted in FIG. 7 but adds exchange tank ET, storage tank T1 and T2, and thermal storage units TS1 and TS2, and the additional components associated therewith as discussed above. The exchange tank ET stores spent cleaning solution from the RT process waste overflow from the chamber C, delivers the waste to tank T1. Tanks T1 and T2 supply waste solution to the cold side loop of HP1 an optimal time for passively heating the loop to improve efficiency of the heat pump.

FIG. 16 illustrates a similar configuration to FIG. 15 but provides HE1 as a passive energy source for input DIW as discussed above. In this embodiment, output of the hot side of HE1 further supplies tank T1, and tanks T1 and T2 supply waste solution to the cold side loop of HP1 as discussed in FIG. 15.

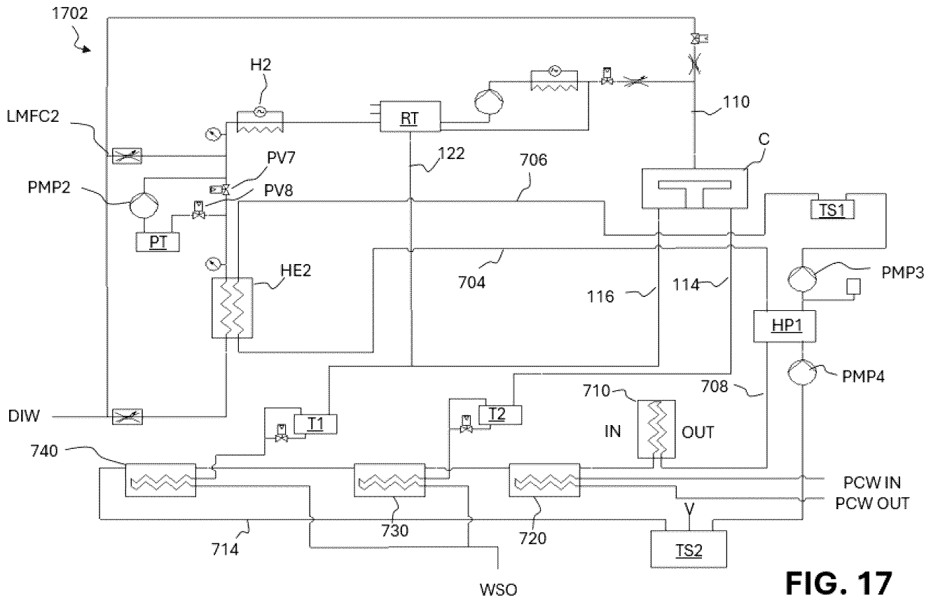

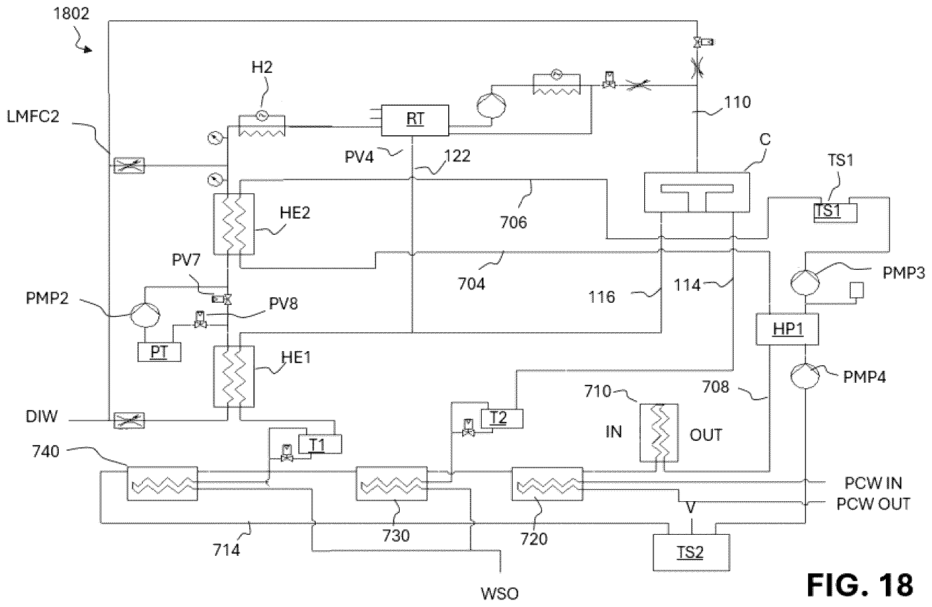

FIG. 17 and FIG. 18 are fluid flow diagrams for a semiconductor processing module which integrates a wafer cleaning chamber with a heat pump, heat exchangers, storage tanks, and a pre-heat tank, for recovery of thermal energy in accordance with example embodiments of the present disclosure. The semiconductor processing module 1702 illustrated in FIG. 17 includes similar components to those depicted in FIG. 7 but adds tanks T1 and T2, thermal storage units TS1 and TS2, and pre-heat tank PT, as well as the associated pumps and valves as discussed above. T1 and T2 deliver store thermal energy from waste fluids and deliver the waste fluids to the cold side loop of HP1. TS1 and TS2 actively heat fluids in the heat pump loops, and PT actively heats DIW to maintain process throughput and improve overall efficiency of the processing module.

The semiconductor processing module 1802 illustrated in FIG. 18 includes similar components to those depicted in FIG. 17 but provides additional heat exchanger HE1 which passively couples thermal energy of the waste fluids to ambient temperature DIW as discussed above. Output of HE1 further supplies the waste to Waste HE 740 to couple thermal energy to the cold side loop of HP1 as also discussed.

While the semiconductor processing modules in FIGS. 7-18 are described with respect to a single-wafer cleaning chamber, any of such single wafer chambers may be substituted with batch-wafer cleaning such as BT described in FIG. 2.

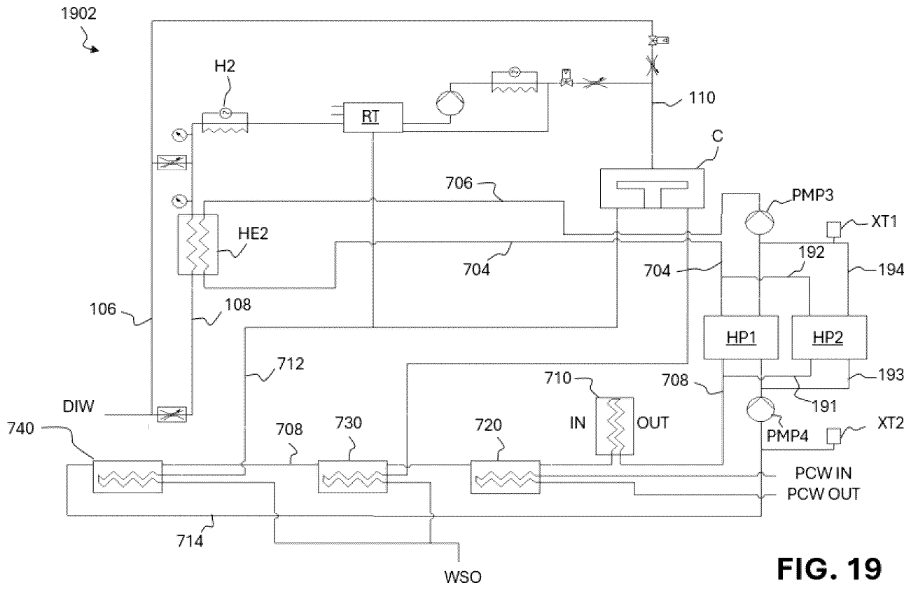

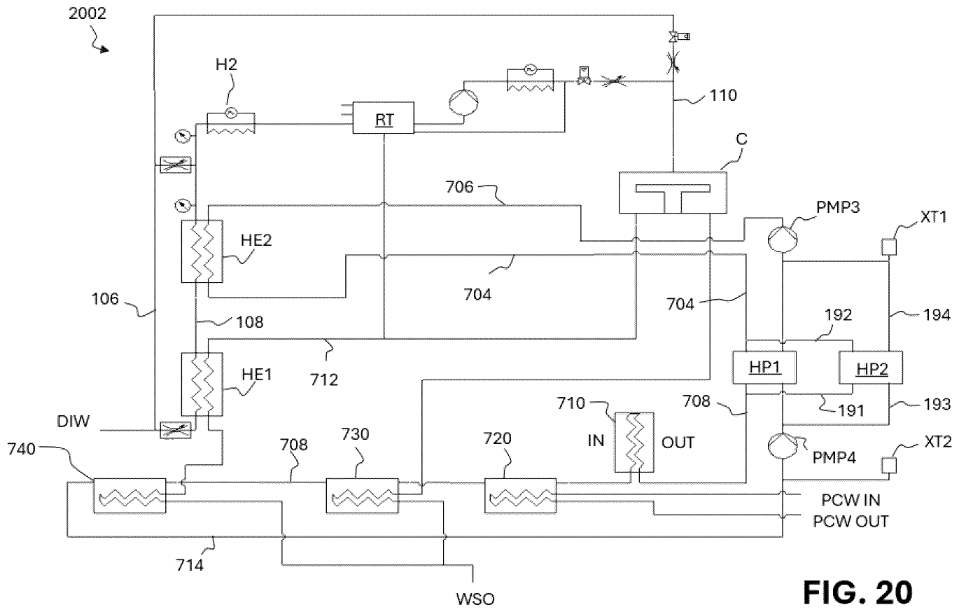

In some embodiments, multiple heat pumps can be provided in series, parallel and/or cascaded configuration to reclaim waste heat and further improve efficiencies of the processing module. FIG. 19 and FIG. 20 are fluid flow diagrams for a semiconductor processing module which integrates a wafer cleaning chamber with parallel heat pumps and heat exchangers for recovery of thermal energy in accordance with example embodiments of the present disclosure. The semiconductor processing chamber module illustrated in FIG. 19 includes similar components to those depicted in FIG. 7 but includes heat pump HP2.

As shown, line 704 on the hot side loop of HP1 branches to line 192 of HP2 and line 706 of the hot loop branches to HP2. Similarly, line 708 of the cold side loop of HP1 branches to line 191 of HP2 and line 714 of the cold-side loop branches to HP2. Accordingly, HP1 and HP2 work in parallel to actively heat ambient DIW via the heat exchanger HE2, and heat exchangers 710, 720, 730, and 740 collect thermal energy from the system to reduce the thermal load of heat pumps HP1 and HP2. This parallel configuration enables HP1 and HP2 to provide higher thermal capacity, load sharing, and redundancy for improved efficiency and reliability of the processing module 1902.

The semiconductor processing module 2002 illustrated in FIG. 20 includes similar components to those depicted in FIG. 19 but adds heat exchanger HE1 as a passive heat source for input DIW input, and drains into waste HE 740 which supplies heat to the cold side loop of HP1 and HP2 as discussed above.

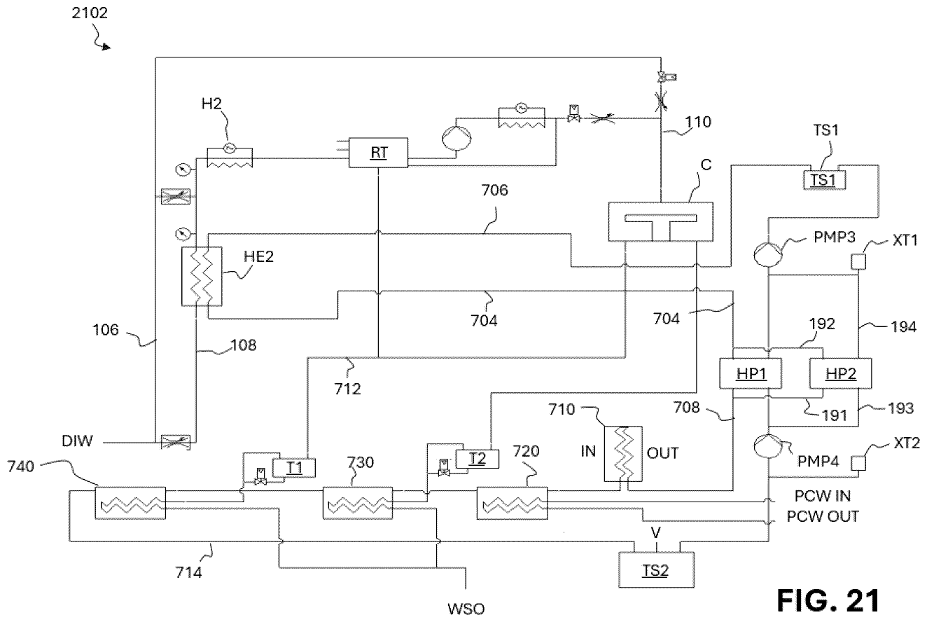

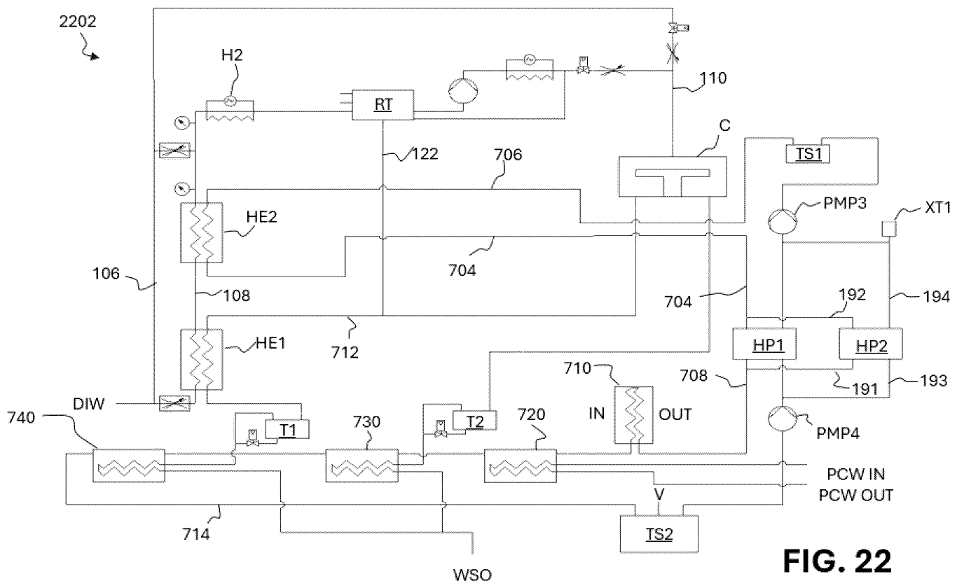

FIG. 21 and FIG. 22 are fluid flow diagrams for a semiconductor processing module which integrates a wafer cleaning chamber with parallel heat pumps, heat exchangers and storage tanks for recovery of thermal energy in accordance with example embodiments of the present disclosure. The semiconductor processing module 2102 illustrated in FIG. 21 includes similar components to those depicted in FIG. 19 but adds tanks T1 and T2, thermal storage units TS1 and TS2, and associated flow components as discussed above. T1 and T2 store thermal energy from waste fluids of the recirculation tank RT and cleaning chamber C, deliver the waste fluids to the cold side loop of HP1/HP2 to reduce their thermal load as discussed. Thermal storage units TS1 and TS2 actively heat fluids on the hot side loop and cold side loop of HP1/HP2 to maintain process throughput and improve efficiency of the processing module.

The semiconductor processing module 2202 illustrated in FIG. 22 includes similar components to those depicted in FIG. 21 but includes heat exchanger HE1 which reclaims waste solution energy for heating input DIW, and flows the waste solution to the cold side loop of HP1/HP2 to improve their efficiency as discussed above.

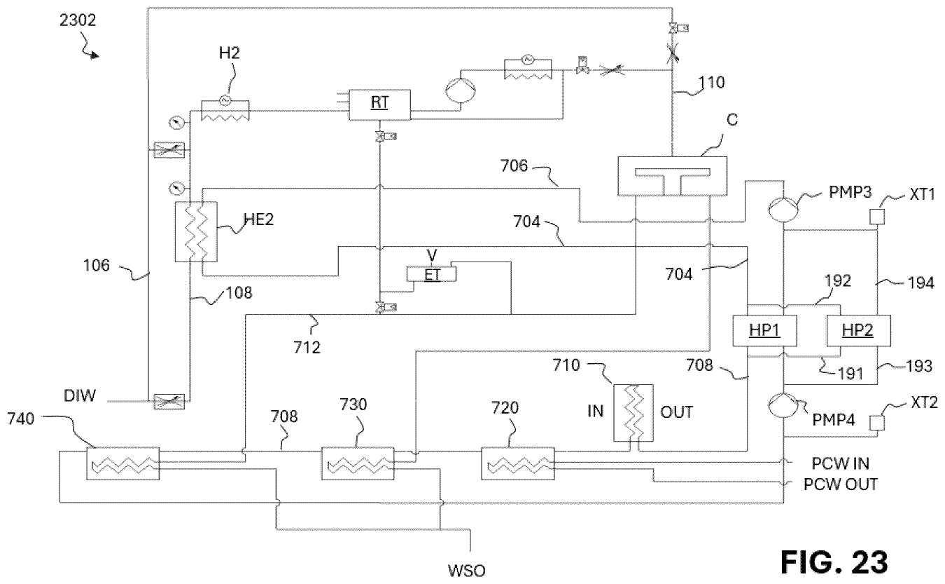

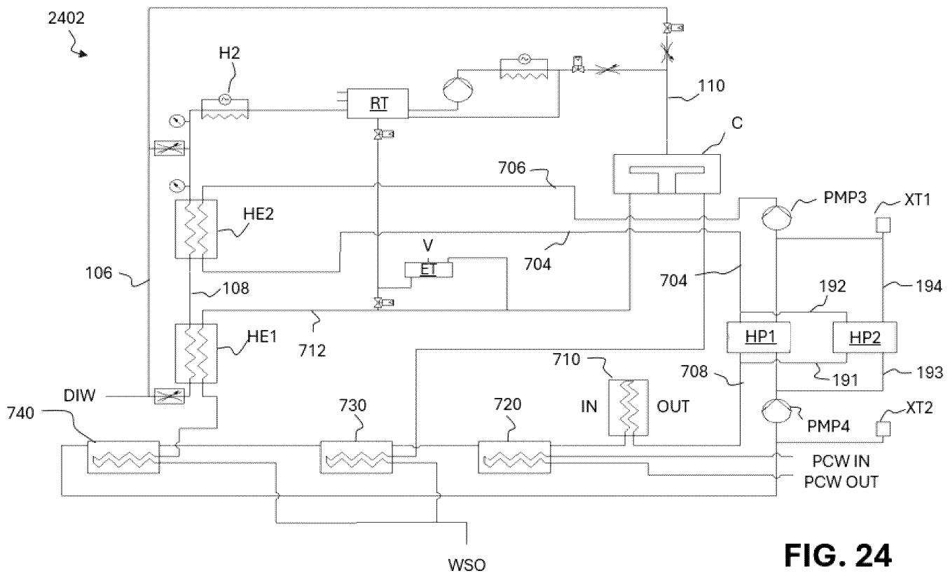

FIG. 23 and FIG. 24 are fluid flow diagrams for a semiconductor processing module which integrates a wafer cleaning chamber with parallel heat pumps, heat exchangers and an exchange tank for recovery of thermal energy in accordance with example embodiments of the present disclosure. The semiconductor processing chamber module 2302 illustrated in FIG. 23 includes similar components to those depicted in FIG. 19 but adds exchange rank ET and associated pneumatic valves as discussed above. The exchange tank ET stores spent cleaning solution and flows the waste to the cold side loop of HP1/HP2 for passively heating the loop to improve efficiency of the heat pumps. The semiconductor processing module 2402 illustrated in FIG. 24 includes similar components to those depicted in FIG. 23 but adds additional heat exchanger HE1. Waste fluids flow from the chamber, RT and ET through HE1 and waste HE 740 to heat incoming DIW and couple thermal energy to the cold side loop of H1/H2.

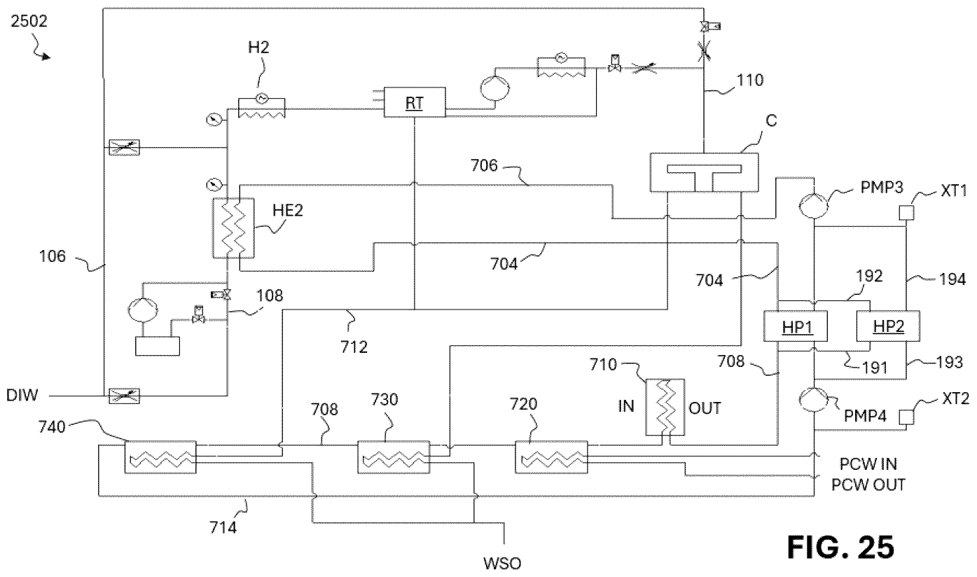

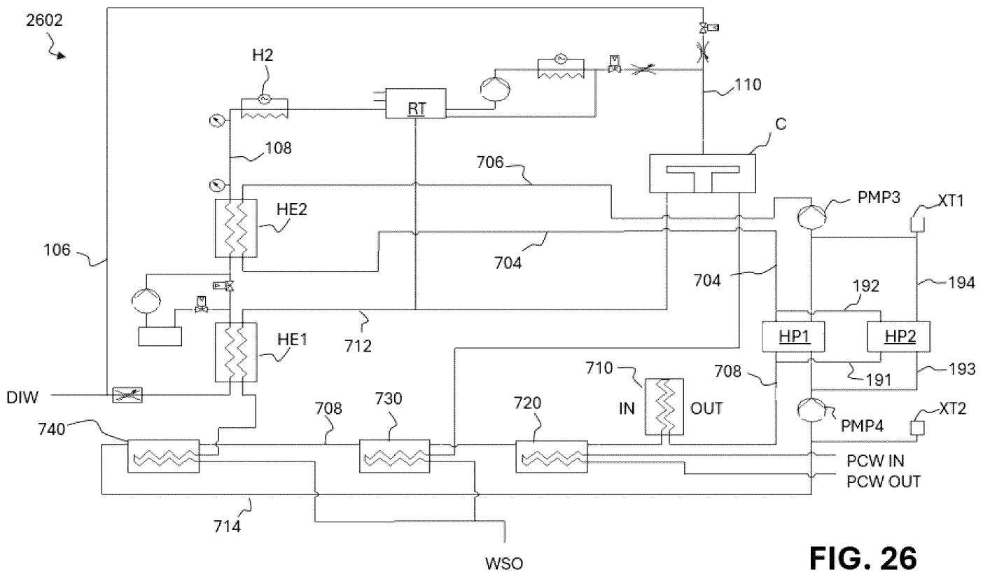

FIG. 25 and FIG. 26 are fluid flow diagrams for a semiconductor processing module which integrates a wafer cleaning chamber with parallel heat pumps, heat exchangers and a pre-heat tank for recovery of thermal energy in accordance with example embodiments of the present disclosure. The semiconductor processing module 2502 illustrated in FIG. 25 includes similar components to those depicted in FIG. 19 but adds a pre-heat tank PT and associated pump and pneumatic valves which supply pre-heated DIW at optimal times for maintaining throughput of the cleaning module as discussed.

The semiconductor processing chamber module 2602 illustrated in FIG. 26 includes similar components to those depicted in FIG. 25 but adds heat exchanger HE1 on DIW input line 108. As such, the preheat tank PT, pump, and pneumatic valves are provided in parallel to line 108 between HE1 and HE2. HE1 uses waste fluid to passively heat the DIW and supplies the waste fluid to the cold loop of HP1/HP2 to reduce their thermal load as discussed above.

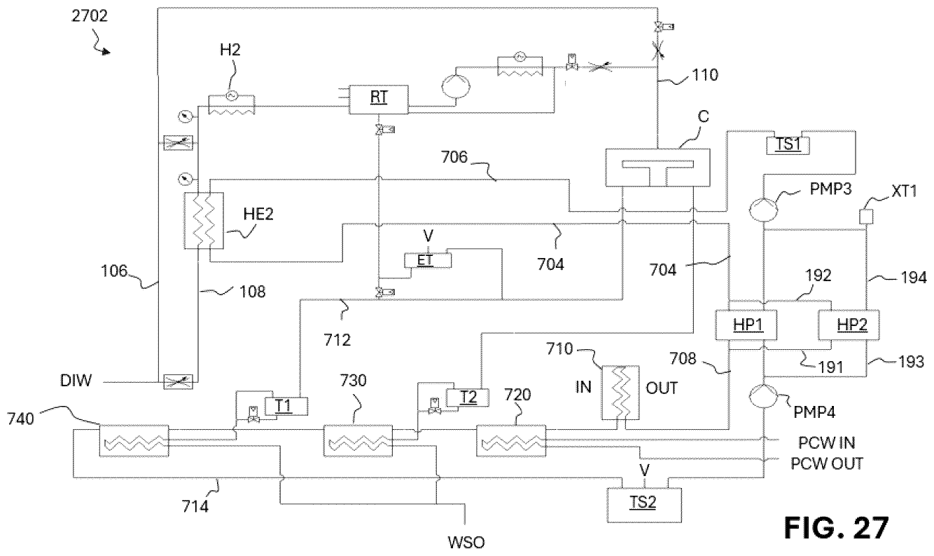

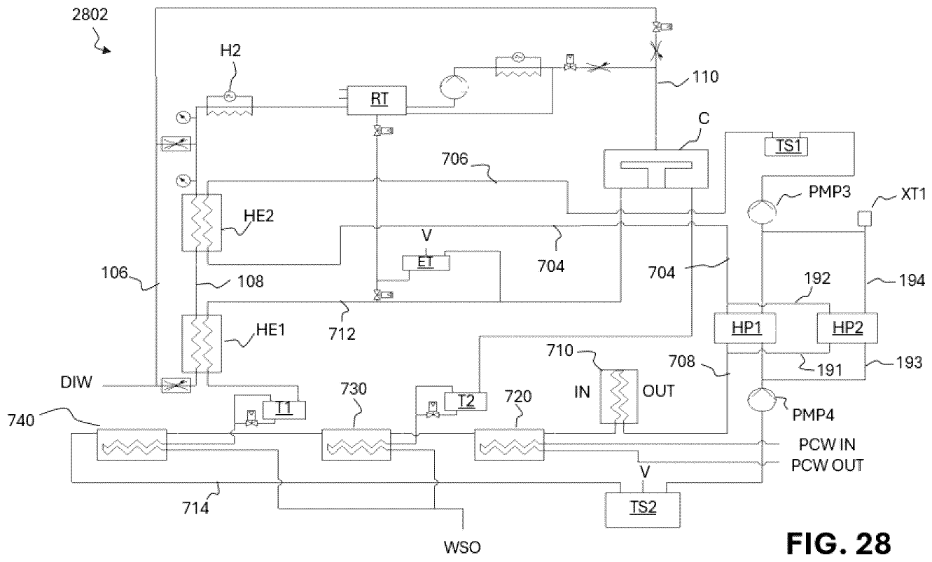

FIG. 27 and FIG. 28 are fluid flow diagrams for a semiconductor processing module which integrates a wafer cleaning chamber with parallel heat pumps, heat exchangers and storage tanks for recovery of thermal energy in accordance with example embodiments of the present disclosure. The semiconductor processing module 2702 illustrated in FIG. 27 includes similar components to those depicted in FIG. 19 but adds exchange tank ET, storage tank T1 and T2, and thermal storage units TS1 and TS2, and the additional components associated therewith as discussed above. The exchange tank ET stores spent cleaning solution from the RT process waste overflow from the chamber C and delivers the waste to tank T1. Tanks T1 and T2 supply waste solution to the cold side loop of HP1 an optimal time for passively heating the loop to improve efficiency of the heat pump.

FIG. 28 illustrates a similar configuration to FIG. 27 but provides HE1 as a passive energy source for input DIW and delivers waste solution to tank T1 which in turn supplies it to the cold side loop of HP1/HP2 to improve their efficiency as discussed above.

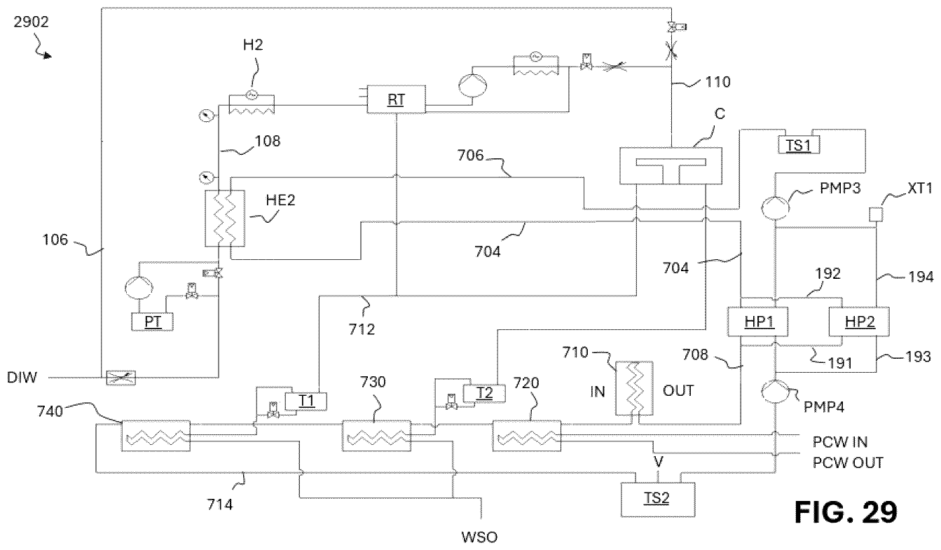

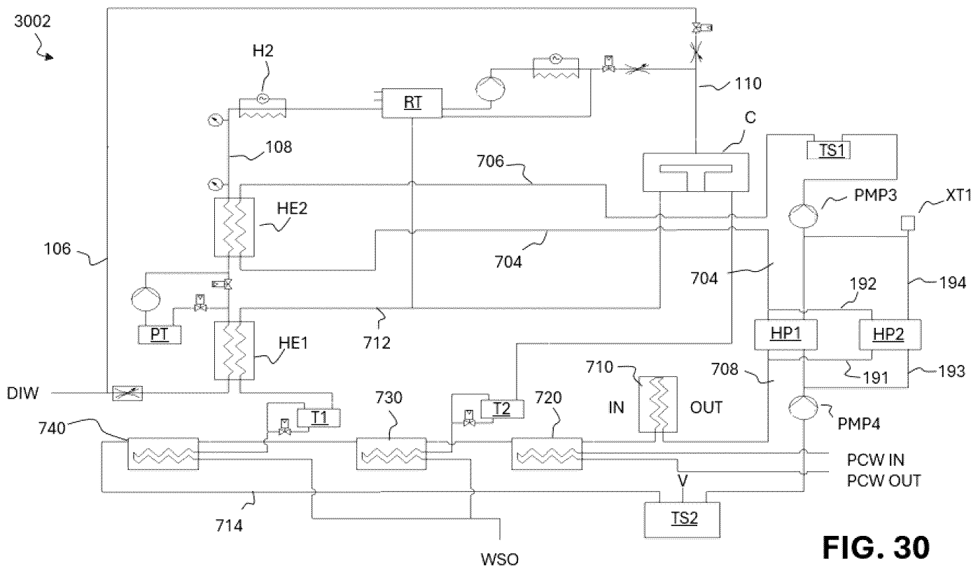

FIG. 29 and FIG. 30 are fluid flow diagrams for a semiconductor processing module which integrates a wafer cleaning chamber with parallel heat pumps, heat exchangers, storage tanks, and a pre-heat tank, for recovery of thermal energy in accordance with example embodiments of the present disclosure. The semiconductor processing module 2902 illustrated in FIG. 29 includes similar components to those depicted in FIG. 19 but adds tanks T1 and T2, thermal storage units TS1 and TS2, and pre-heat tank PT, as well as the associated pumps and valves. T1 and T2 store thermal energy from waste fluids and deliver the waste fluids to the cold side loop of HP1/HP2, and TS1 and TS2 actively heat fluids on the hot and cold loops of the parallel heat pumps as discussed. The semiconductor processing module 3002 illustrated in FIG. 30 includes similar components to those depicted in FIG. 29 but provides additional heat exchanger HE1 in similar configuration to those discussed above.

Parallel-connected heat pumps are desirable when the goal is high flow capacity and efficiency at modest temperature lifts. Each pump handles the same temperature range, making them ideal for large loads with minimal lift, and allowing straightforward scalability. They offer excellent redundancy, simpler piping, and easy load matching, making them well-suited for systems with variable or high-volume demands.

While the semiconductor processing modules in FIGS. 19-30 are described with respect to a single-wafer cleaning chamber, any of such single wafer chambers may be substituted with batch-wafer cleaning such as BT described in FIG. 2.

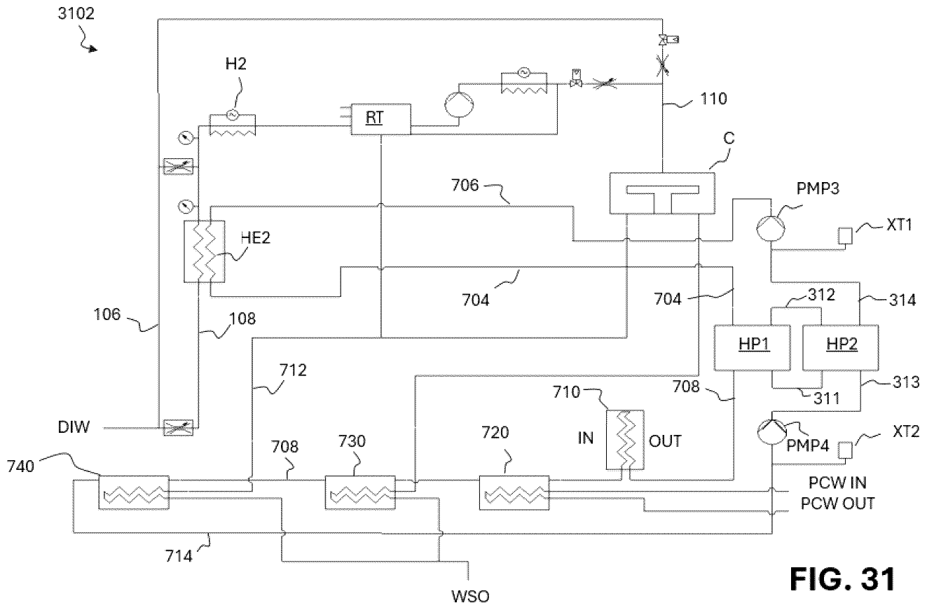

FIG. 31 is a fluid flow diagram for a semiconductor processing module which integrates a wafer cleaning chamber with series connected heat pumps and heat exchangers for recovery of thermal energy in accordance with example embodiments of the present disclosure. The semiconductor processing chamber module illustrated in FIG. 31 includes similar components to those depicted in FIG. 19 but provides the heat pumps H1 and H2 in series. As shown, HP1 outputs fluid on line 704 which flows through heat exchanger HE2 and returns on line 706 via pump PMP3 which returns the flow through line 314 to heat pump HP2 which is directly connected to HP1 by line 312 to complete the hot loop side for the heat pumps. Similarly, line 708 of the cold side loop of HP1/HP2 flows through heat exchangers 710, 720, 730 and 740 and flows through line 714 to pump PMP4 and returns to HP2 through line 313. HP2 is directly connected to HP1 through line 311 to complete the cold loop of the heat pump system.

This series-connected heat pumps of FIG. 31 provides a high temperature lift when compared to parallel configured heat pumps which are generally for improving flow capacity. The processing modules in any one FIGS. 20-30 may be modified to replace or reconfigure heat pumps H1 and H2 to be in series as shown in FIG. 31.

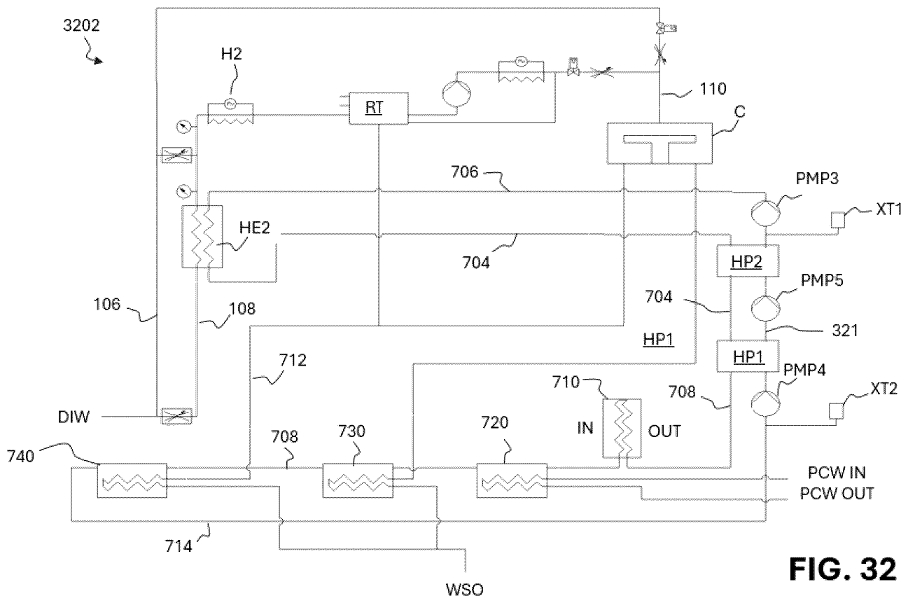

FIG. 32 is a fluid flow diagram for a semiconductor processing module which integrates a wafer cleaning chamber with cascaded heat pumps and heat exchangers for recovery of thermal energy in accordance with example embodiments of the present disclosure. The semiconductor processing chamber module illustrated in FIG. 32 includes similar components to those depicted in FIG. 19 but provides the heat pumps HP1 and HP2 in a cascaded configuration. As shown, a hot side of HP1 is connected to a clod side of HP2 by line 321 and line 323 via pump PMP5. The hot loop of the heat pump system flows through line 704, heat exchanger HE2 and back to HP2 via pump PMP3. Similarly, line 708 of the cold side loop of the heat pump system flows through heat exchangers 710, 720, 730 and 740 and flows through line 714 to HP2 via pump PMP4. Thus, the module of FIG. 32 provides H1 and H2 in a cascaded heat pump configuration which can achieve much higher temperature lifts than series or parallel systems. The processing modules in any one FIGS. 20-30 may be modified to replace or reconfigure heat pumps H1 and H2 to be in cascaded configuration as shown in FIG. 32.

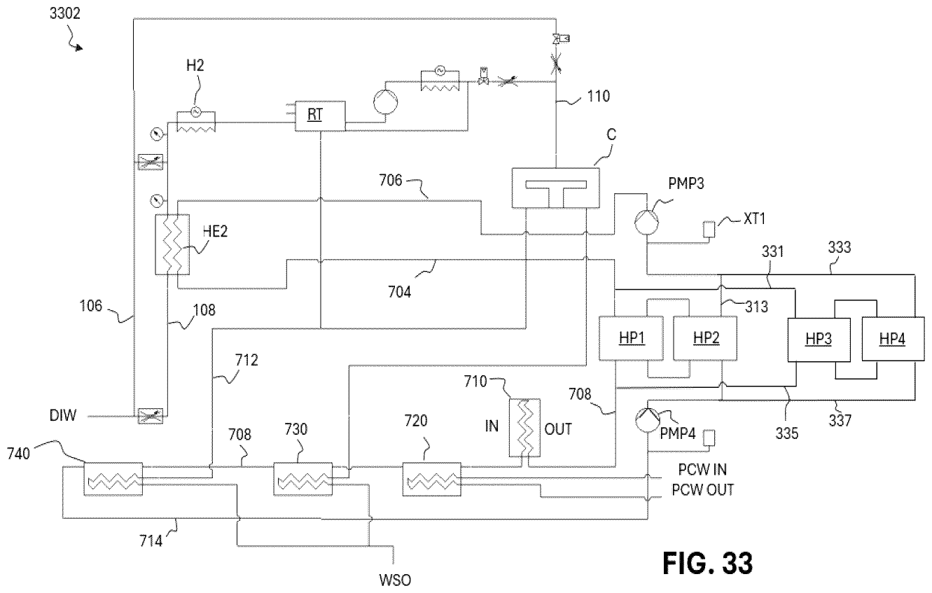

Series, parallel, and cascaded heat pump configurations can be strategically combined to achieve the desired capacity, temperature lift, and efficiency for a given application. For example, FIG. 33 illustrates a module 3302 with heat pumps HP1 and HP2 arranged in series, heat pumps HP3 and HP4 also arranged in series, with these two series pairs HP1/HP2 and HP3/HP4 connected in parallel to each other. On the cold side, line 708 branches to line 335 such that HP1 and HP3 are fed in parallel, and the discharge from PMP4 branches to line 337 which supplies the cold side of HP2 and HP4. On the hot side, the outlets from HP1 and HP3 (line 331) converge on line 704, while the outlets from HP2 and HP4 converge on line 333 to feed PMP3. This combined arrangement allows the system to benefit from the higher temperature lift of series operation within each pair, while the parallel connection of the two series pairs increases total capacity and offers operational flexibility.

While the semiconductor processing modules in FIGS. 31-33 are described with respect to a single-wafer cleaning chamber, any of such single wafer chambers may be substituted with batch-wafer cleaning such as BT described in FIG. 2.

In one embodiment, multiple heat pumps may be configured to be arranged in a combination of parallel, series, and cascade with heat exchangers (HE) in a semiconductor processing chamber module for single-wafer cleaning and batch wafer cleaning.

In one embodiment, multiple heat pumps may be configured to be arranged in a combination of parallel, series, and cascade with one or more thermal storage (TS), and one or more thermal storage resistance heaters (TSRH) in a semiconductor processing chamber module for single-wafer cleaning and batch wafer cleaning.

In one embodiment, multiple heat pumps may be configured to be arranged in a combination of parallel, series, and cascade with heat exchangers (HE), one or more thermal storages (TS), and one or more thermal storage resistance heaters (TSRH) in a semiconductor processing chamber module for single-wafer cleaning and batch wafer cleaning.

In one embodiment, multiple heat pumps may be configured to be arranged in a combination of parallel, series, and cascade with exchange tanks (ET) in a semiconductor processing chamber module for single-wafer cleaning and batch wafer cleaning.

In one embodiment, multiple heat pumps may be configured to be arranged in a combination of parallel, series, and cascade with exchange tanks (ET) and heat exchangers (HE) in a semiconductor processing chamber module for single-wafer cleaning and batch wafer cleaning.

FIG. 34 is a block diagram illustrating an example information processing device that may be used to perform or facilitate control of and of the any of the processing modules of FIGS. 1-33 in accordance with embodiments of the present disclosure. As shown, the information processing device 3400 includes a processor 3401, a memory 3402, an auxiliary storage device 3403, an interface device 3404, a communication device 3405, and a drive device 3406. The hardware components of the information processing device are connected to each other via a bus 3407. Further, Display device 3421, operation device 3423, external device 3425, and recording medium 3427 may be coupled to the information processing apparatus 3400.

The processor 3401 includes various computing devices such as a central processing unit (CPU), a graphics processing unit (GPU), and the like. The processor 3401 reads various programs on the memory 3402 and executes the programs.

The memory 3402 includes a main storage device such as a read only memory (ROM), a random access memory (RAM), and the like. The processor 3401 and the memory 3402 form what is called a computer, and the computer achieves various functions by the processor 3401 executing various programs that are read on the memory 3402.

The auxiliary storage device 3403 stores various programs and various types of data used when the various programs are executed by the processor 3401. The tool-specific error data, tool model and/or physical model described above may be implemented in the auxiliary storage device 3403. Further, software modules for performing the functionality described herein may be implemented in the auxiliary storage device 3403.

The I/F device 3404 is a connection device that connects the information processing apparatus 3400 with an external device 3425 via a hard-wired connection for example.

The display device 3421 is a device that displays an internal state of the information processing apparatus 3400. The operation device 3423 is an input device used when a user of the information processing apparatus 3400 inputs various types of instructions to the information processing apparatus 3400. The I/F device 3407 is a connection device for connecting to, and communicating with, a network (not shown).

The communication device 3405 is a communication device for communicating with external device 3425 via a network (not shown).

The drive device 3406 is a device for setting a recording medium 3427. The recording medium 3427 herein includes a medium optically, electrically, or magnetically recording information, such as a CD-ROM, a flexible disk, or a magneto-optical disk. Additionally, the recording medium 3410 may include a semiconductor memory or the like that electrically records information, such as a ROM, a flash memory, or the like.

The various programs installed in the auxiliary storage device 3403 are installed by, for example, the recording medium 3427 being set in the drive device 3406 and the various programs recorded in the recording medium 3427 being read by the drive device 3406. Alternatively, the various programs installed in the auxiliary storage device 3403 may be installed by being downloaded from a network via the communication device 3405.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Components and/or functionality described with respect to any embodiment disclosed herein can be combined with any other embodiment disclosed herein. For example, the recirculation tank RT in any module can be configured to supply a processing solution to two or more processing chambers. Further, one or more temperature sensors and flow valves may be used in any disclosed module to ensure that hot waste is sent to a thermal coupler for reclaiming heat and cold waste will bypass any thermal coupler configured to reclaim heat. As another example, any heat pump described herein can include one or more of the source loop heat exchangers described herein. Further, the source loop of any heat exchanger can receive thermal energy coupled from hot waste of the system or from an external heat source, or from both the hot waste and an external source. In one example embodiment, the source loop of a heat pump can be configured to receive thermal energy coupled only from process cooling water of a cooling system configured to cool one or more processing tools in a semiconductor fabrication facility. Fluids circulating of any of the heat pumps, thermal coupling devices and/or heat exchangers described herein may be a heat transfer fluid, a refrigerant, or any fluid suitable for system operating conditions. Any fluid tank described herein may include passive thermal storage features such as phase transfer materials and/or an active thermal heating mechanism such as a resistive heater.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A system comprising:
one or more semiconductor processing chambers;
a processing fluid supply system comprising:
an input portion configured to receive a first fluid from a first fluid source,
a heater fluidly coupled to the input portion and configured to heat the first fluid, and
a heated flow portion fluidly coupled to the heater and configured to deliver a heated processing fluid comprising the first fluid heated by the heater to the one or more semiconductor processing chambers;
a waste system configured to receive hot waste fluid from at least one of the heated flow portion and the one or more semiconductor processing chambers; and
a heat exchanger comprising a supply-side flow path in fluid communication with the input portion and a heat delivery-side flow path in fluid communication with the waste system, wherein the heat exchanger is configured to transfer thermal energy from the waste system to the input portion to heat the first fluid prior to heating by the heater.

2. The system of claim 1, wherein the heated flow portion comprises a recirculation tank configured to input the first fluid heated by the heater and to output the heated processing fluid for delivery to the one or more semiconductor processing chambers.

3. The system of claim 2, wherein the heated flow portion comprises a recirculation loop configured to return the heated processing fluid output from the recirculation tank back into the recirculation tank.

4. The system of claim 3, wherein the recirculation loop comprises a circulation pump and a recirculation heater.

5. The system of claim 2, wherein the recirculation tank is configured to input at least a second fluid for mixing with the first fluid to provide the heated processing fluid for delivery to the one or more semiconductor processing chambers.

6. The system of claim 1, further comprising a rinse delivery system configured to provide a rinse fluid to the one or more semiconductor processing chambers.

7. The system of claim 6, wherein the rinse delivery system is configured to receive the first fluid from the first fluid source and provide the first fluid as the rinse fluid to the one or more semiconductor processing chambers.

8. The system of claim 6, further comprising at least one valve configured to flow either the heated processing fluid or the rinse fluid to the semiconductor processing chamber.

9. The system of claim 1, wherein the one or more semiconductor processing chambers comprises a batch wafer cleaning chamber or a single wafer cleaning chamber.

10. The system of claim 1, wherein the one or more semiconductor processing chambers comprises a plurality semiconductor processing chambers.

11. The system of claim 2, wherein the waste system comprises an exchange tank configured to store hot waste fluid from the recirculation tank and selectively flow stored hot waste fluid to the heat delivery-side flow path of the heat exchanger.

12. The system of claim 11, wherein the waste system comprises a drain line configured to drain the hot waste fluid from the recirculation tank into the exchange tank.

13. The system of claim 12, wherein the drain line comprises at least one flow valve configured to selectively flow the hot waste fluid from the recirculation tank into the exchange tank, and selectively flow the stored hot waste fluid to the heat delivery-side flow path of the heat exchanger.

14. The system of claim 1, wherein the input portion of the processing fluid supply system comprises a pre-heating flow system configured to pre-heat the first fluid.

15. The system of claim 14, wherein the pre-heating flow system comprises a pre-heating tank configured to store pre-heated first fluid and flow stored pre-heated first fluid to the heater.

16. The system of claim 15, wherein the pre-heating flow system further comprises a pre-heat pump and at least one flow valve configured to selectively flow the stored pre-heated first fluid to the heater.

17. The system of claim 15, wherein the pre-heating tank further comprises a heater configured to heat fluid within the pre-heating tank.

18. A method comprising:
providing a fluid supply system coupled to at least one semiconductor processing chamber configured to process a semiconductor substrate;
flowing a first fluid via an input portion of the fluid supply system to a heater; using the heater to heat the first fluid and outputting a heated first fluid to a heated flow portion of the fluid supply system which flows a heated processing fluid comprising the heated first fluid to the semiconductor processing chamber;
collecting hot waste fluid from at least one of the heated flow portion of the fluid supply system and the semiconductor processing chamber; and
coupling thermal energy from the hot waste fluid to the first fluid prior to using the heater to heat the first fluid such that a thermal load on the heater is reduced.

19. The method of claim 18, further comprising:
providing a recirculation tank on the input portion of the fluid supply system;
draining the hot waste fluid from the recirculation tank to an exchange tank configured to store the drained hot waste fluid;
selectively flowing stored hot waste fluid from the exchange tank to a thermal coupling device; and
using the thermal coupling device to couple thermal energy from the hot waste fluid to the first fluid prior to using the heater to heat the first fluid such that a thermal load on the heater is reduced.

20. The method of claim 18, further comprising:
providing a pre-heating tank on the input portion of the fluid supply system, the pre-heating tank being configured to store preheated first fluid; and
selectively flowing pre-heated first fluid from the pre-heating tank to the heater such that a thermal load on the heater is reduced.
